(19) United States
(12) Patent Application Publication
(10) Pub. No.: US 2026/0016744 A1
(43) Pub. Date: Jan. 15, 2026

(54) NANOSHAPE PATTERNING TECHNIQUES THAT ALLOW HIGH-THROUGHPUT FABRICATION OF FUNCTIONAL NANOSTRUCTURES WITH COMPLEX GEOMETRIES ON PLANAR AND NON-PLANAR SUBSTRATES

(71) Applicant: Board of Regents, The University of Texas System, Austin, TX (US)

(72) Inventors: Sidlgata V. Sreenivasan, Austin, TX (US); Parth Pandya, Austin, TX (US); David Choi, Austin, TX (US); John Ekerdt, Austin, TX (US)

(21) Appl. No.: 18/845,992

(22) PCT Filed: Mar. 11, 2023
(86) PCT No.: PCT/US2023/015043

§ 371 Date: Sep. 11, 2024

Related U.S. Application Data
(60) Provisional application No. 63/319,060, filed on Mar. 11, 2022.
(60) Provisional application No. 63/344,481, filed on May 20, 2022.
(60) Provisional application No. 63/353,128, filed on Jun. 17, 2022.

(51) Int. Cl. G03F 7/00; B29C 33/38; B29D 11/00; B29L 11/00; G02B 6/136

(52) U.S. Cl. CPC G03F 7/0002; B29C 33/3842; B29D 11/00663; G03F 7/0005; B29K 2909/02; B29L 2011/0075; G02B 6/136

(57) ABSTRACT

A method for fabricating functional optical components. A detackable adhesive layer is deposited on an intermediate substrate. A curable liquid is deposited onto the detackable adhesive layer on the intermediate substrate. An imprint template is used to transfer patterns onto the curable liquid followed by curing thereby forming an imprinted patterned material on the intermediate substrate. A layer of functional material is deposited on the imprinted patterned material. Furthermore, a polymer layer is deposited on top of the functional material layer. A correlated etch of the polymer layer and the functional material layer is then performed thereby forming an etched functional material surface. The etched functional material surface is bonded to a final substrate. The imprinted patterned material is then detacked from the intermediate substrate at the detackable adhesive layer.

### TECHNICAL FIELD

The present invention relates generally to fabrication of nanostructures, and more particularly to nanoshape patterning techniques that allow high-throughput fabrication of functional nanostructures with complex geometries on planar and non-planar substrates.

### BACKGROUND

Nanostructures, nanomaterials, and nanocomposites can be fabricated using various techniques. One technique is the top-down approach which involves lateral patterning of bulk materials by either subtractive or additive methods to realize nano-sized structures. Several methods are used to fabricate nanostructures using the top-down approach, such as photolithography, scanning lithography, laser machining, soft lithography, nanocontact printing, nanosphere lithography, colloidal lithography, scanning probe lithography, ion implantation, diffusion, deposition, etc. Another technique is the bottom-up approach in which nanostructures are fabricated by building upon single atoms or molecules. In this method, controlled segregation of atoms or molecules occurs as they are assembled into desired nanostructures (2-10 nm size range).

Unfortunately, these techniques are deficient in terms of high-throughput fabrication of functional nanostructures with complex geometries on planar and non-planar substrates.

### SUMMARY

In one embodiment of the present disclosure, a method for fabricating multi-tiered, multi-graded imprint lithography templates comprises depositing a first profiled polymer layer onto a patterned multi-tiered primary material, where the patterned multi-tiered primary material comprises a hard mask on a top surface. The method further comprises etching the first profiled polymer layer and the patterned multi-tiered primary material thereby forming a graded depth in a lower tier of the multi-tiered primary material. The method additionally comprises selectively removing the etched first profiled polymer layer thereby forming an intermediate multi-tiered multi-graded primary material. Furthermore, the method comprises selectively stripping the hard mask from a top surface of the intermediate multi-tiered multi-graded primary material to create a hard mask free intermediate multi-tiered multi-graded primary material. Additionally, the method comprises depositing a second profiled polymer layer onto the hard mask free intermediate multiticred multi-graded primary material. In addition, the method comprises etching the second profiled polymer layer and the patterned multi-tiered primary material thereby forming a profiled surface comprising regions of the second profiled polymer and regions of the patterned multi-ticred primary material, where a top tier of the multi-tiered primary material has been etched along with the second profiled polymer layer. The method further comprises selectively removing the etched second profiled polymer layer thereby forming a final patterned multi-tiered multi-graded primary material.

In anther embodiment of the present disclosure, a method for fabricating multi-tiered, multi-graded imprint lithography templates comprises depositing a first profiled polymer layer onto a patterned multi-tiered primary material. The method further comprises etching the first profiled polymer layer and the patterned multi-tiered primary material thereby forming a composite profiled surface comprising regions of the first profiled polymer layer and regions of the patterned multi-tiered primary material, where a top tier of the multi-tiered primary material has been etched along with the first profiled polymer layer. The method additionally comprises selectively depositing a hard mask cap on to the regions of the patterned multi-tiered primary material on the composite profiled surface. Furthermore, the method comprises selectively removing the etched first profiled polymer layer thereby forming an intermediate multi-tiered multi-graded primary material. Additionally, the method comprises depositing a second profiled polymer layer onto the intermediate multi-tiered multi-graded primary material. In addition, the method comprises etching the second profiled polymer layer and the patterned multi-tiered primary material thereby forming a graded depth in a lower tier of the multi-tiered primary material. Furthermore, the method comprises selectively removing the etched second profiled polymer layer thereby forming a patterned multi-tiered multi-graded primary material with a hard mask.

In a further embodiment of the present disclosure, a method for fabricating functional optical components comprises depositing a detackable adhesive layer on an intermediate substrate. The method further comprises depositing a curable liquid onto the detackable adhesive layer on the intermediate substrate. The method additionally comprises using an imprint template to transfer patterns onto the curable liquid followed by curing thereby forming an imprinted patterned material on the intermediate substrate. Furthermore, the method comprises depositing a layer of functional material on the imprinted patterned material. Additionally, the method comprises depositing a polymer layer on top of the functional material layer. In addition, the method comprises performing a correlated etch of the polymer layer and the functional material layer thereby forming an etched functional material surface, where a correlated etch implies that there is a substantially defined etch selectivity between the polymer layer and the functional material layer. In one embodiment, the functional material is Si, Ga or Ti. In one embodiment, the functional material has a refractive index exceeding 1.6 in the visible spectrum. The method further comprises bonding the etched functional material surface to a final substrate. The method additionally comprises detacking the imprinted patterned material from the intermediate substrate at the detackable adhesive layer.

In another embodiment of the present disclosure, a method for fabricating diffractive optical elements with customizable pattern heights comprises patterning nanostructures on a substrate. The method further comprises depositing one or more layers of contrasting material over the patterned nanostructures. The method additionally comprises custom profiling the contrasting material forming a custom profile. Furthermore, the method comprises etching the custom profile into the patterned nanostructures thereby producing a patterned nanostructure with custom pattern heights with trenches filled with the contrasting material. Additionally, the method comprises eliminating the contrasting material from the trenches leaving behind the nanostructure with custom pattern heights.

In a further embodiment of the present disclosure, a method for fabricating multi-layered diffractive optical elements comprises patterning nanostructures of high index material. The method further comprises depositing low index material over the patterned nanostructure of the high index material as an inter-fill. The method additionally comprises planarizing the low index material thereby forming a single layer of high index nanostructure with planarized low index material inter-fill. Furthermore, the method comprises bonding the single layer of high index nanostructure with planarized low index material inter-fill to another single layer of the high index nanostructure with planarized low index material inter-fill.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIGS. 1A-1E illustrate the overall fabrication process of a multi-tiered, multi-graded depth, grand-daughter template in accordance with an embodiment of the present disclosure;

FIG. 2 is a flowchart of a method for fabricating a multi-tiered, uniform-depth replica template (MURT) in accordance with an embodiment of the present disclosure;

FIGS. 3A-3C depict the cross-sectional views for fabricating a multi-tiered, uniform-depth replica template (MURT) using the steps described in FIG. 2 in accordance with an embodiment of the present disclosure;

FIGS. 4A-4C depict images of templates in connection with method 200 of FIG. 2 in accordance with an embodiment of the present disclosure;

FIG. 5 is a flowchart of a method for fabricating a multi-tiered, uniform-depth working template (MUWT) in accordance with an embodiment of the present disclosure;

FIGS. 6A-6C depict the cross-sectional views for fabricating a multi-tiered, uniform-depth working template (MUWT) using the steps described in FIG. 5 in accordance with an embodiment of the present disclosure;

FIGS. 7A-7B depict the web handling module for handling the web and FIG. 7C illustrates the resulting web using the steps described in FIG. 5 in accordance with an embodiment of the present disclosure;

FIG. 8 is a flowchart of a method for fabricating a multi-tiered, uniform-depth grand-daughter template (MUGTD) in accordance with an embodiment of the present disclosure;

FIGS. 9A-9H depict the cross-sectional views for fabricating a multi-tiered, uniform-depth grand-daughter template (MUGTD) using the steps described in FIG. 8 in accordance with an embodiment of the present disclosure;

FIGS. 10A-10H depict the utilization of the web handling module for fabricating the MUGTD in accordance with an embodiment of the present disclosure;

FIG. 11 is a flowchart of a method for fabricating a multi-tiered, multi-graded grand-daughter template (MMGTD) without an initial hard mask in accordance with an embodiment of the present disclosure;

FIGS. 12A-12H depict the cross-sectional views for fabricating a multi-tiered, multi-graded grand-daughter template (MMGTD) without an initial hard mask using the steps described in FIG. 11 in accordance with an embodiment of the present disclosure;

FIG. 13 is a flowchart of a method for fabricating a multi-tiered, multi-graded grand-daughter template (MMGTD) with an initial mask in accordance with an embodiment of the present disclosure;

FIGS. 14A-14H depict the cross-sectional views fabricating a multi-tiered, multi-graded grand-daughter template (MMGTD) with an initial mask using the steps described in FIG. 13 in accordance with an embodiment of the present disclosure;

FIGS. 15A-15F illustrate the overall fabrication process of high-refractive index multi-graded depth inorganic waveguides (HMIWs) on high-index wafers in accordance with an embodiment of the present disclosure;

FIG. 16 is a flowchart of a method for fabricating a multi-tiered, multi-graded super-master (MMS) in accordance with an embodiment of the present disclosure;

FIGS. 17A-17E depict the cross-sectional views for fabricating a multi-tiered, multi-graded super-master (MMS) using the steps described in FIG. 16 in accordance with an embodiment of the present disclosure;

FIGS. 18A-18E depict images of structures in connection with method 1600 of FIG. 16 in accordance with an embodiment of the present disclosure;

FIG. 19 is a flowchart of a method for fabricating a multi-tiered, multi-graded working template (MMW) in accordance with an embodiment of the present disclosure;

FIGS. 20A-20C depict the cross-sectional views for fabricating a multi-tiered, multi-graded working template (MMW) using the steps described in FIG. 19 in accordance with an embodiment of the present disclosure;

FIGS. 21A-21B depict the web handling module for handling the web and FIG. 21C illustrates the resulting web using the steps described in FIG. 19 in accordance with an embodiment of the present disclosure;

FIG. 22 is a flowchart of a method for fabricating a high-index multi-graded depth inorganic waveguide (HMMW) on high-index wafers in accordance with an embodiment of the present disclosure;

FIGS. 23A-23H depict the cross-sectional views for fabricating a high-index multi-graded depth inorganic waveguide (HMMW) on high-index wafers using the steps described in FIG. 22 in accordance with an embodiment of the present disclosure;

FIGS. 24A-24H depict the utilization of the web handling module for fabricating the HMMW in accordance with an embodiment of the present disclosure;

FIGS. 25A-25B illustrate HMIW options for coverage of high index material bonded to a 300 mm wafer in accordance with an embodiment of the present disclosure;

FIGS. 26A-26E illustrate various template types in accordance with an embodiment of the present invention;

FIGS. 27A-27C illustrate exit pupil expansion (EPE) in diffraction grating in accordance with an embodiment of the present disclosure;

FIG. 28 illustrates a lightguide with two-dimensional periodic grating structures (diamond-shaped) in accordance with an embodiment of the present disclosure;

FIGS. 29A-29B illustrate an exemplary manufacturing system architecture for fabricating customized beam splitting gratings for applications, such as facial recognition, in accordance with an embodiment of the present disclosure;

FIGS. 30A-30B illustrate the steps for fabricating a high volume template for applications, such as facial recognition, in accordance with an embodiment of the present disclosure;

FIG. 31 is a flowchart of a method for fabricating polymer nanostructures with customized multi-graded features in accordance with an embodiment of the present disclosure;

FIGS. 32A-32E depict the cross-sectional views for fabricating polymer nanostructures with customized multi-graded features using the steps described in FIG. 31 in accordance with an embodiment of the present disclosure;

FIG. 33 is a flowchart of a method for fabricating inorganic nanostructures with customized multi-graded features in accordance with an embodiment of the present disclosure;

FIGS. 34A-34D depict the cross-sectional views for fabricating inorganic nanostructures with customized multi-graded features using the steps described in FIG. 33 in accordance with an embodiment of the present disclosure;

FIGS. 35A-35L illustrate the various nanostructures and materials that include the input and output gratings of diffractive optical elements used in applications, such as XR, in accordance with an embodiment of the present disclosure;

FIG. 36 is a flowchart of a method for fabricating high index inorganic waveguides with exemplar multi-tier, multi-graded nanostructures and a low index planar in accordance with an embodiment of the present disclosure;

FIGS. 37A-37C depict the cross-sectional views for fabricating high index inorganic waveguides with exemplar multi-tier, multi-graded nanostructures and a low index planar using the steps of FIG. 36 in accordance with an embodiment of the present disclosure;

FIG. 38 is a flowchart of a method for fabricating multi-layer high index nanostructures for applications, such as XR, in accordance with an embodiment of the present disclosure;

FIGS. 39A-39F depict the cross-sectional views for fabricating multi-layer high index nanostructures for applications, such as XR, using the steps of FIG. 38 in accordance with an embodiment of the present disclosure;

FIG. 40 is a flowchart of a method for fabricating multi-layer high index nanostructures with precise overlay for applications, such as augmented reality, in accordance with an embodiment of the present disclosure;

FIGS. 41A-41D depict the cross-sectional views for fabricating multi-layer high index nanostructures with precise overlay using the steps of FIG. 40 in accordance with an embodiment of the present disclosure;

FIGS. 42A-42C illustrate a large area substrate typically made of glass with multiple cutouts of eyewear shaped devices in accordance with an embodiment of the present disclosure;

FIG. 43 is a flowchart of a method for performing the nHOC process with a light switchable adhesive as a detacking layer followed by planarization in accordance with an embodiment of the present disclosure; and

FIGS. 44A-44J depict the cross-sectional views for performing the nHOC process with a light switchable adhesive as a detacking layer followed by planarization using the steps of FIG. 43 in accordance with an embodiment of the present disclosure.

### DETAILED DESCRIPTION

As stated in the Background section, nanostructures, nanomaterials, and nanocomposites can be fabricated using various techniques. One technique is the top-down approach which involves lateral patterning of bulk materials by either subtractive or additive methods to realize nano-sized structures. Several methods are used to fabricate nanostructures using the top-down approach, such as photolithography, scanning lithography, laser machining, soft lithography, nanocontact printing, nanosphere lithography, colloidal lithography, scanning probe lithography, ion implantation, diffusion, deposition, etc. Another technique is the bottom-up approach in which nanostructures are fabricated by building upon single atoms or molecules. In this method, controlled segregation of atoms or molecules occurs as they are assembled into desired nanostructures (2-10 nm size range).

Unfortunately, these techniques are deficient in terms of high-throughput fabrication of functional nanostructures with complex geometries on planar and non-planar substrates.

The embodiments of the present disclosure provide a means for providing high-throughput fabrication of functional nanostructures with complex geometries on planar and non-planar substrates as discussed below.

Applications in photonics can benefit from using nanostructures made of high refractive index materials, such as Si₃N₄, TiO₂, and high refractive index glasses (M100 series from Asahi Glass Company, Realview Series from Schott®, and 2.0 refractive index glass from Corning® Advanced Optics). However, etching of nanoscale features into such high index materials is difficult due to the inability to create volatile reactants in etching processes. Typically, ion milling is used to etch nanoscale features into high index materials which is prone to defects. Nanostructured polymer materials have also been used, but they typically do not possess refractive indices as high as inorganic materials. Furthermore, nanostructured polymer materials have performance issues related to changes in refractive index with wavelength as well as scalability issues due to inconsistent optical performance arising from material composition variability. As discussed herein, the principles of the present disclosure utilize a process referred to hercin as “Nanofabrication of High Index Optical Components (nHOC)” which can enable the use of nanostructured inorganic high index materials with the capability of high volume manufacturing. This process involves 2 major steps: (1) fabricating a working template from a master template for high volume nanopattern replication; and (2) fabricating complex nanostructures in high index materials on various types of substrates using the aforementioned working template and vacuum deposition of inorganic high index materials.

Furthermore, exemplary nHOC processes are discussed below for applications which require a curved substrate, such as lens blanks, as well as for applications that require slanted nanopatterns in high refractive index materials. Furthermore, the nHOC process of the present disclosure may be utilized for the fabrication of Augmented Reality (AR) and Mixed Reality (MR), collectively called XR, waveguides and waveguide combiners with nanostructures that form key components, such as the input grating, eyebox expansion and output grating. These structures may have patterns that are multi-tiered as well as with a spatially varying gradient in the depth for each tier (referred to as “multi-tiered, multi-graded depth”). Additionally, the principles of the present disclosure utilize elements from International Publication No. WO 2021/173873 and International Publication No. WO 2021/252389, which are incorporated by reference herein in their entirety.

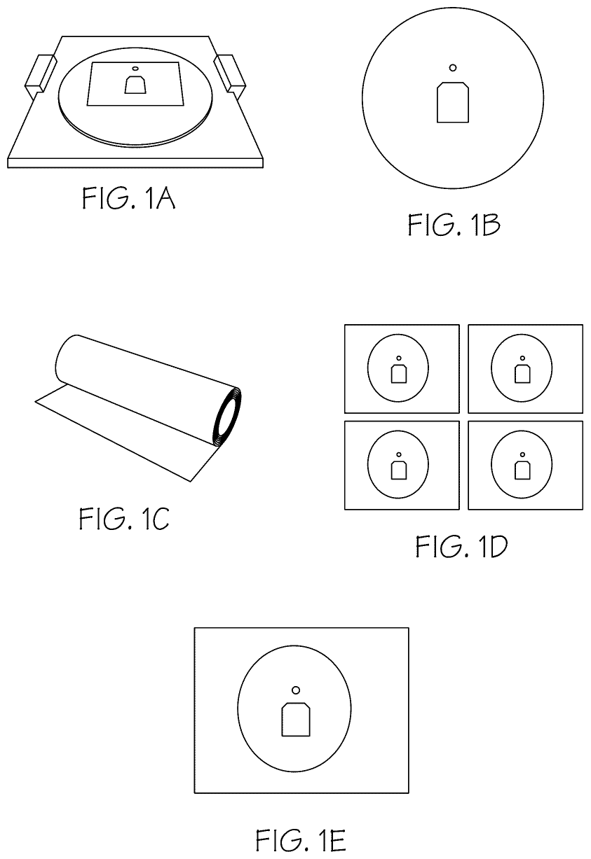

Referring now to the Figures, FIGS. 1A-1E illustrate the overall fabrication process of a multi-tiered, multi-graded depth, grand-daughter template in accordance with an embodiment of the present disclosure.

In particular, FIG. 1A illustrates the multi-tiered uniform-depth master (MUM) with both the grating structures. FIG. 1B illustrates the multi-tiered, uniform-depth replicate template (MURT). In one embodiment, the MURT has an inverse tone compared to the MUM. Inverting the tone implies that the recesses become protrusions and vice-versa and maintaining the original tone implies that the recesses remain recesses and protrusions remain as protrusions. FIG. 1C illustrates the multi-tiered, uniform-depth working template (MUWT), where in one embodiment, the MUWT has an inverse tone. FIG. 1D illustrates the multi-tiered, uniform-depth grand-daughter templates (MUGDT), where in one embodiment, the MUGDT has the original tone compared to the MUM. FIG. 1E illustrates the multi-tiered, multi-graded depth grand-daughter template (MMGDT).

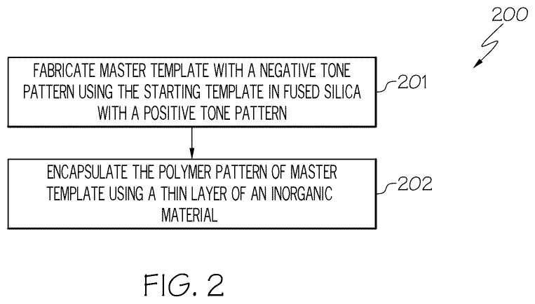

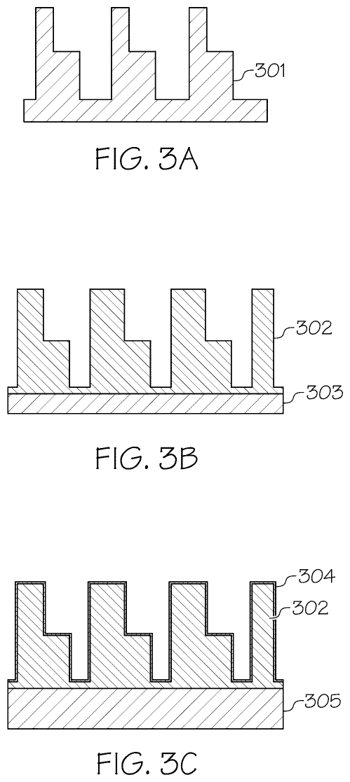

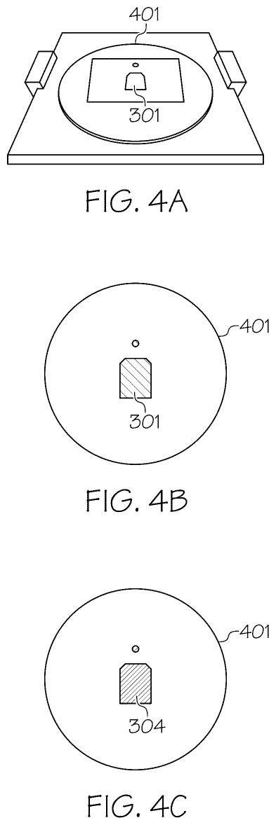

Referring now to FIG. 2, FIG. 2 is a flowchart of a method 200 for fabricating a multi-tiered, uniform-depth replica template (MURT) in accordance with an embodiment of the present disclosure. FIGS. 3A-3C depict the cross-sectional views for fabricating a multi-tiered, uniform-depth replica template (MURT) using the steps described in FIG. 2 in accordance with an embodiment of the present disclosure. FIGS. 4A-4C depict images of templates in connection with method 200 in accordance with an embodiment of the present disclosure.

Referring to FIG. 2, in conjunction with FIGS. 3A-3C and 4A-4C, in step 201, a nanoimprint lithography super master template 302 is fabricated using e-beam lithography, photolithography or other patterning techniques. In one embodiment, super master template 302 has a negative tone pattern as shown in FIGS. 3B and 4B. In one embodiment, the starting (or “master”) template 301 in fused silica with a positive tone pattern, as shown in FIGS. 3A and 4A, is used to make the “super master” template 302. In one embodiment, FIGS. 3A and 4A illustrate the multi-tiered, uniform-depth master template 301 in fused silica with nanoscale patterns, including input and output grating structures. In particular, FIG. 4A illustrates master template 301 on wafer 401.

In one embodiment, a copy of master template 301 is made forming “super master template” 302 with multiple fields. In one embodiment, super master template 302 is formed via the use of nanoimprint lithography using master template 301. An illustration of an inversion of master template 301 on wafer 401 is shown in FIG. 4B.

Furthermore, FIG. 3B illustrates a layer of resist on silicon 303 of super master template 302. In one embodiment, nanoimprint lithography super master template 302 has nanopatterns with multiple tiers.

In one embodiment, a replica of master template 301 is fabricated on substrate 303 that is substantially rigid (e.g., Si, SiO₂). In one embodiment, this replica is a super master template 302 which consists of a polymer pattern with an inverse tone to that of master template 301, where the polymer can be a UV-crosslinked polymer, and where the pattern is fabricated using nanoimprint lithography. In one embodiment, FIGS. 3B and 4B depict the patterning of both input grating and output grating structures for MURT.

In step 202, the polymer pattern of super master template 302 is encapsulated using a thin (<20 nm) layer of an inorganic material 304, such as Au, SiO₂, and Si₃N₄, which can be deposited using PVD or low-temperature CVD techniques, where the substrate 305 now includes the resist on silicon with the thin inorganic material (MURT) as shown in FIGS. 3C and 4C. That is, FIGS. 3C and 4C illustrate coating the resist with inorganic film to finish MURT. In particular, FIG. 4C illustrates super mater template 302 encapsulated with inorganic material 304 on wafer 401. In one embodiment, the pattern shown in FIG. 3C has a negative tone.

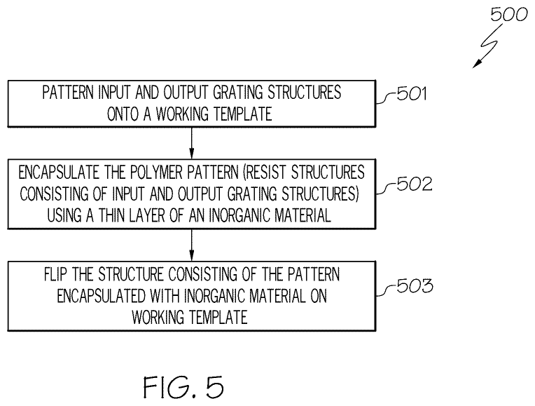

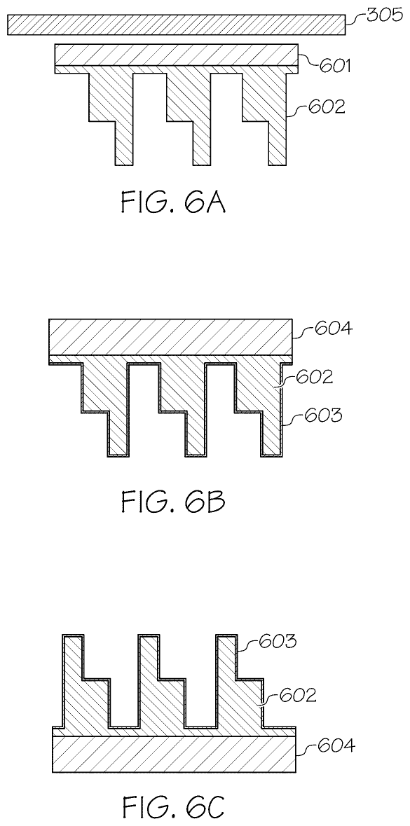

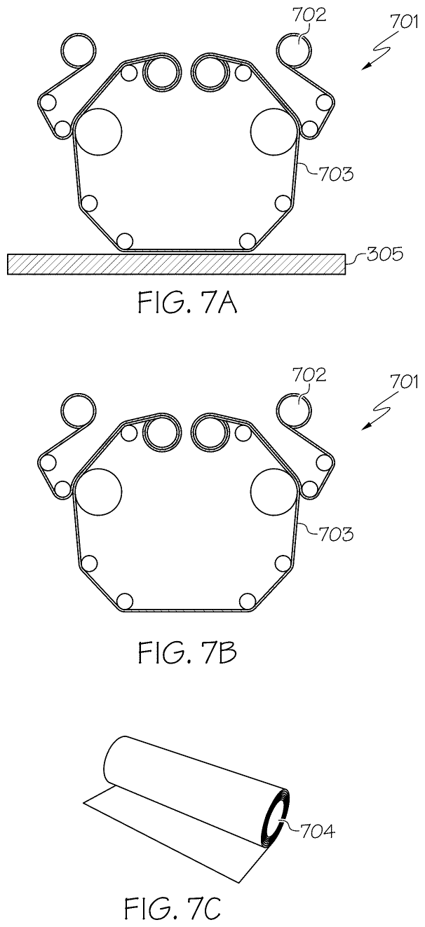

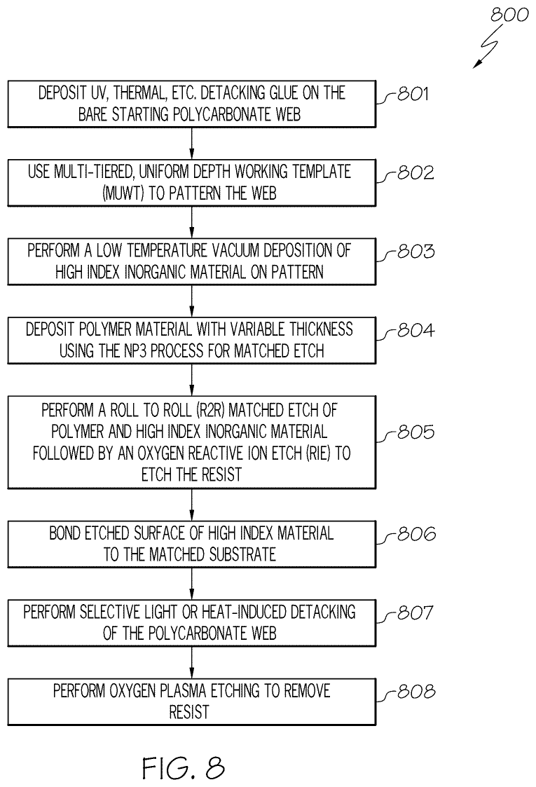

Referring now to FIG. 5, FIG. 5 is a flowchart of a method 500 for fabricating a multi-tiered, uniform-depth working template (MUWT) in accordance with an embodiment of the present disclosure. FIGS. 6A-6C depict the cross-sectional views for fabricating a multi-tiered, uniform-depth working template (MUWT) using the steps described in FIG. 5 in accordance with an embodiment of the present disclosure. FIGS. 7A-7B depict the web handling module 701 for handling the web and FIG. 7C illustrates the resulting web using the steps described in FIG. 5 in accordance with an embodiment of the present disclosure.

Referring to FIG. 5, in conjunction with FIGS. 6A-6C and 7A-7C, in step 501, the input and output grating structures 602 (also referred to herein as “polymer pattern” 602) are patterned on a working template 601 using the structure shown in FIGS. 3C and 4C. An illustration of such patterning is shown in FIGS. 6A and 7A. In one embodiment, working template 601 corresponds to the resist on the polycarbonate (PC) web. FIG. 7A illustrates a web handling module 701 consisting of unwind and rewind rollers 702 to pattern MURT 305 on working template 601 using web 703. In one embodiment, polymer pattern 602 of working template 601 has a positive tone.

In step 502, polymer pattern 602 (resist structures consisting of input and output grating structures) of working template 601 is encapsulated using a thin (<20 nm) layer of an inorganic material 603, such as Au, SiO₂, and Si₃N₄, which can be deposited using PVD or low-temperature CVD techniques, where the substrate (working template) 604 now includes the polymer replica with the thin inorganic coating on the polycarbonate. In one embodiment, such an encapsulation is performed using the web handling module 701 of FIG. 7B. In one embodiment, polymer pattern 602 encapsulated with inorganic material 603 has a positive tone.

In optional step 503, the structure shown in FIG. 6B consisting of pattern 602 encapsulated with inorganic material 603 on working template 604 forms the finished MUWT as shown in FIG. 6C. The resulting polycarbonate web 704 is depicted in FIG. 7C, which is now available for use. In one embodiment, the pattern of the finished MUWT has a positive tone. In one embodiment, working template 604 is flipped to form the finished MUWT.

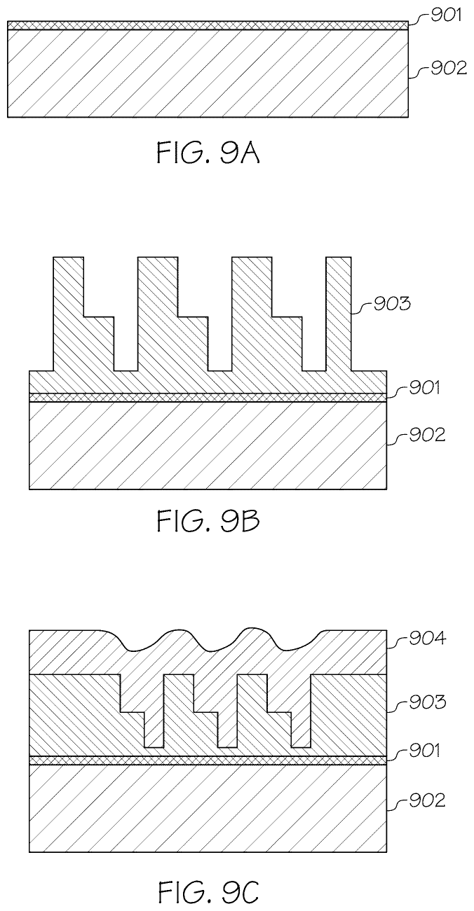

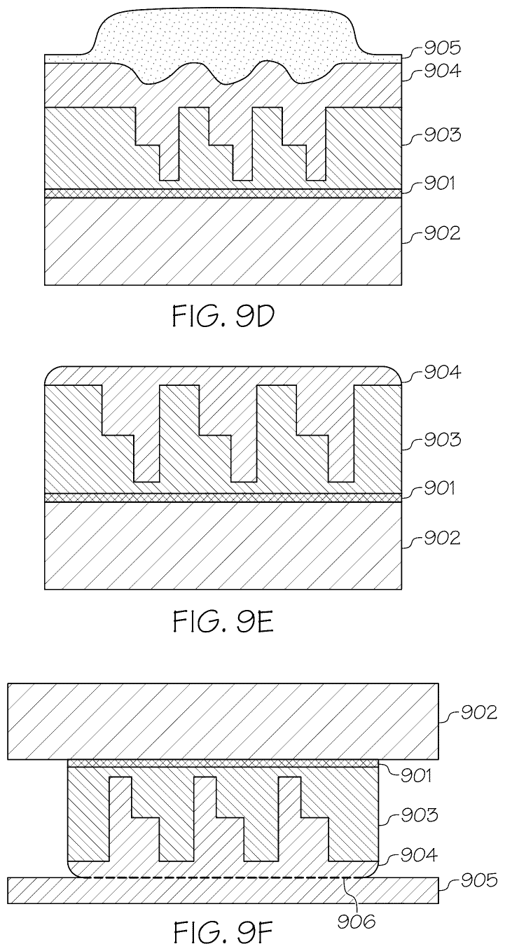

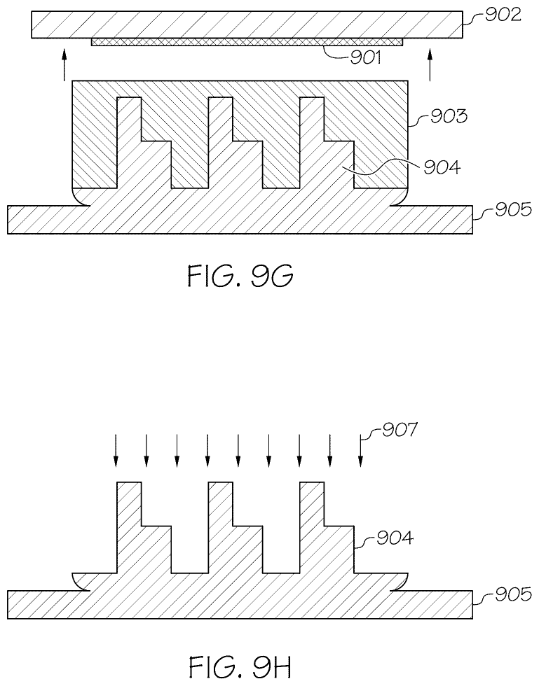

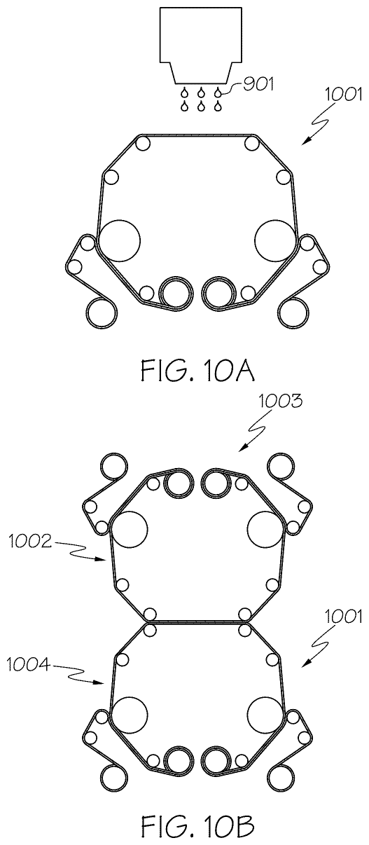

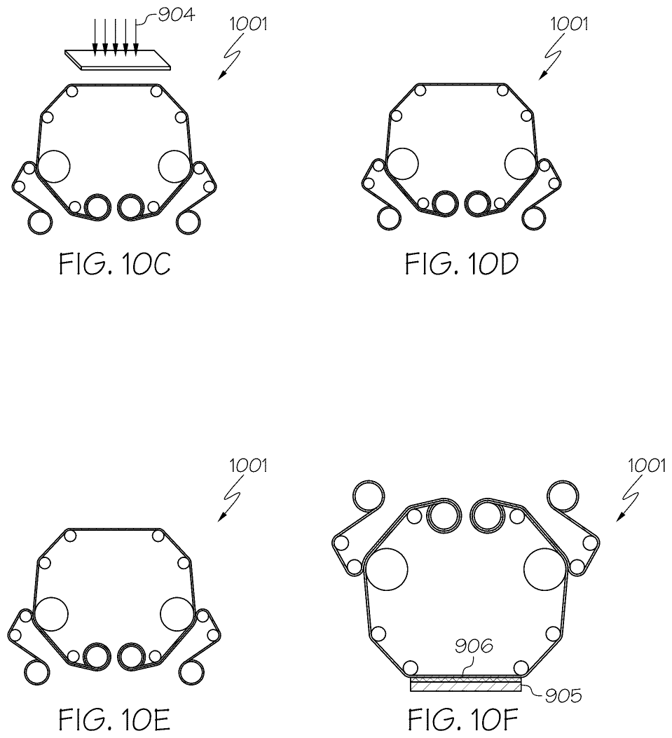

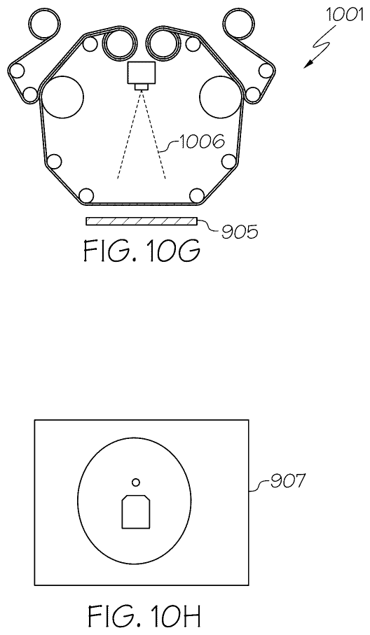

Referring now to FIG. 8, FIG. 8 is a flowchart of a method 800 for fabricating a multi-tiered, uniform-depth grand-daughter template (MUGTD) in accordance with an embodiment of the present disclosure. FIGS. 9A-9H depict the cross-sectional views for fabricating a multi-tiered, uniform-depth grand-daughter template (MUGTD) using the steps described in FIG. 8 in accordance with an embodiment of the present disclosure. FIGS. 10A-10H depict the utilization of the web handling module for fabricating the MUGTD in accordance with an embodiment of the present disclosure.

Referring to FIG. 8, in conjunction with FIGS. 9A-9H and 10A-10H, in step 801, UV, thermal, etc. detacking glue 901 is deposited on the bare starting polycarbonate web 902 (working template) as shown in FIG. 9A. FIG. 10A illustrates web handling module 1001 for depositing glue 901 on bare starting polycarbonate web 902. In one embodiment, detacking glue 901 solidifies upon exposure to visible light and liquifies upon exposure to UV light. Examples of such detacking glue 901 include a light switchable adhesive, such as AuraPeel from Polylux.

In step 802, a multi-tiered, uniform depth working template (MUWT) is used to pattern the web forming pattern 903 on glue 901 as shown in FIG. 9B. In one embodiment, pattern 903 has a negative tone. FIG. 10B illustrates MUWT 1002 of web handling module 1003 as well as the web 1004 patterned with MUWT using web handling module 1001.

In step 803, the vacuum deposition of an inorganic material 904 (e.g., oxide/nitride material) on pattern 903 is performed as shown in FIG. 9C. In one embodiment, pattern 903 has a negative tone. FIG. 10C illustrates the vacuum deposition of inorganic material 904 on pattern 903 using web handling module 1001. Examples of such inorganic material 904 include oxides, nitrides, and carbides, such as SiO₂, Si₃N₄, SiC, etc. In one embodiment, the vacuum deposition of inorganic material 904 is performed at a temperature of <200° C.

In step 804, polymer material 905 with variable thickness is deposited using the nP3 process for matched etch as shown in FIG. 9D. A discussion regarding the nP3 process is provided in International Application No. PCT/US2021/019732, which is incorporated by reference herein in its entirety. FIG. 10D illustrates web handling module 1001 for performing such a deposition.

In step 805, in one embodiment, a roll to roll (R2R) matched etch of polymer and high index inorganic material 904 (e.g., polymer/oxide, polymer/nitride) followed by an oxygen reactive ion etch (RIE) to etch the resist is performed resulting in the structure shown in FIG. 9E. FIG. 10E illustrates web handling module 1001 for performing such an operation.

In step 806, the etched surface of high index material 904 is bonded to the matched substrate 905 with polycarbonate web 906 on top of matched substrate 905 as shown in FIG. 9F. FIG. 10F illustrates web handling module 1001 for performing such an operation.

In step 807, selective light or heat-induced detacking of the polycarbonate web 906 is performed forming the structure as shown in FIG. 9G. FIG. 10G illustrates web handling module 1001 for performing such an operation using light or heat 1005.

In step 808, oxygen plasma ashing 907 is performed to remove resist 903 as shown in FIG. 9H. In one embodiment, such a pattern (see element 904) has a positive tone on the matched substrate 905 (e.g., fused silica). Oxygen plasma ashing 907 is depicted in FIG. 10H.

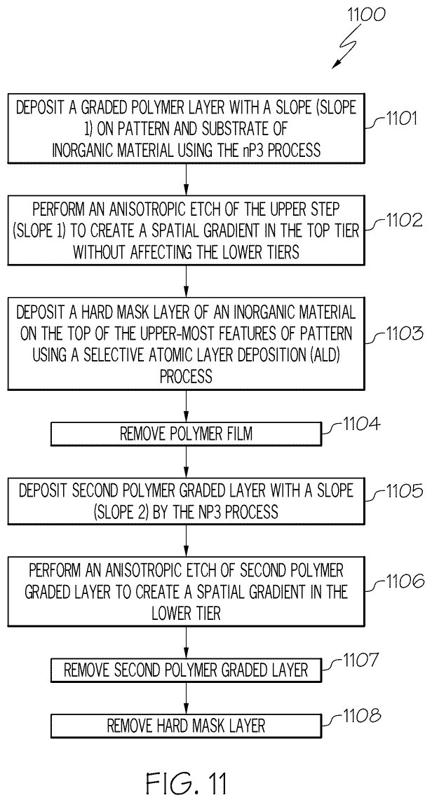

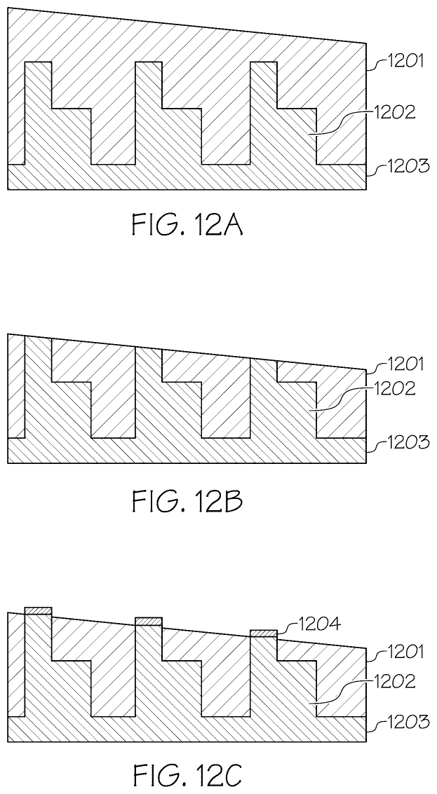

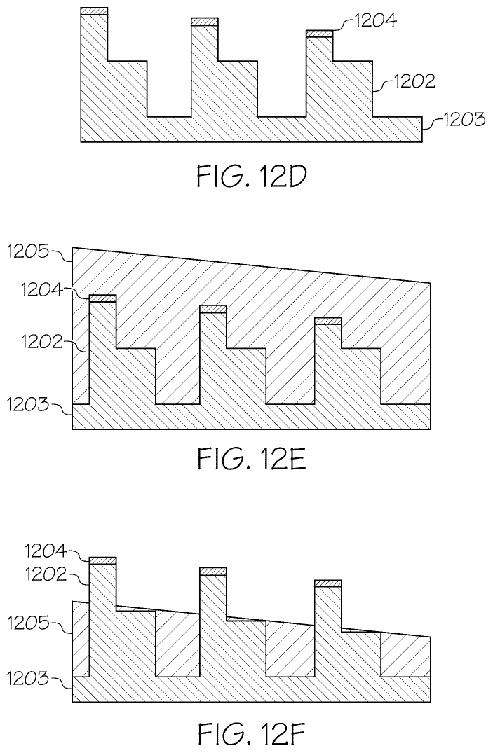

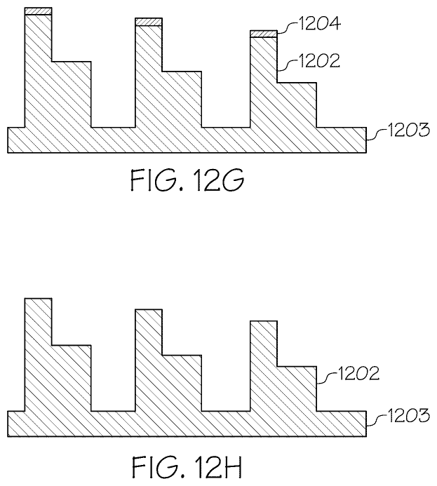

Referring now to FIG. 11, FIG. 11 is a flowchart of a method 1100 for fabricating a multi-tiered, multi-graded grand-daughter template (MMGTD) without an initial hard mask in accordance with an embodiment of the present disclosure. FIGS. 12A-12H depict the cross-sectional views for fabricating the MMGTD without an initial hard mask using the steps described in FIG. 11 in accordance with an embodiment of the present disclosure.

Referring to FIG. 11, in conjunction with FIGS. 12A-12H, in step 1101, a graded polymer layer 1201 with a slope (slope 1) is deposited on pattern 1202 (has a positive tone) and substrate 1203 of inorganic material, such as fused silicon, using the nP3 process as shown in FIG. 12A.

In step 1102, an etch of the upper step (slope 1) is performed to create a spatial gradient in the top tier without affecting the lower tiers as they are “submerged” within polymer film 1201 as shown in FIG. 12B. As shown in FIG. 12B, in one embodiment, the top portions of the top tiers of pattern 1202 are removed in a downward slanted direction corresponding to slope 1. In one embodiment, the etch is substantially anisotropic.

In step 1103, a hard mask layer 1204 of an inorganic material is deposited on the top of the upper-most features of pattern 1202 using a selective atomic layer deposition (ALD) process, such that layer 1204 is deposited only on the exposed fused silica and not on the polymer as shown in FIG. 12C. In one embodiment, hard mask 1204 includes one or more of the following materials, such as Cr, CrO, CrON, MoSiO, MoSiON, CrF, SiN, CrN, CrOCN, SiCrO, WSi and ZrSiO. In one embodiment, the selective ALD process deposits oxides (e.g., an oxide of titanium, TiOₓ), nitrides and metals (e.g., Pt, Pd) as layer 1204.

In step 1104, polymer film 1201 is removed, such as via Piranha cleaning, O₂ plasma ashing, UV ozone or other oxidizing unit processes as shown in FIG. 12D.

In step 1105, a second polymer graded layer 1205 with a slope (slope 2) is deposited by the nP3 process, consistent with the desired gradient of the second tier as shown in FIG. 12E.

In step 1106, an etch of second polymer graded layer 1205 is performed to create a spatial gradient in the lower tier without affecting the higher tiers as shown in FIG. 12F. As shown in FIG. 12F, in one embodiment, the top portions of the bottom tiers of pattern 1202 are removed in a downward slanted direction corresponding to slope 2. In one embodiment, the etch is substantially anisotropic.

In one embodiment, the process of steps 1101-1106 are repeated until all the tiers have achieved the desired gradient.

In step 1107, second polymer graded layer 1205 is removed, such as via Piranha cleaning, O₂ plasma ashing, UV ozone or other oxidizing unit processes as shown in FIG. 12G.

In step 1108, hard mask layer 1204 is removed, such as via wet stripping, as shown in FIG. 12H.

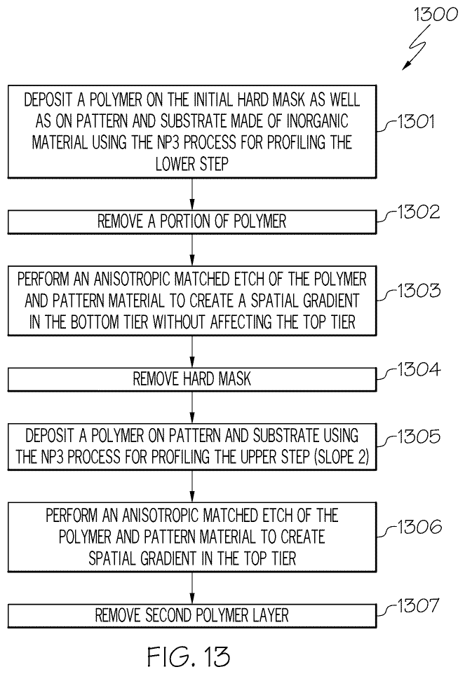

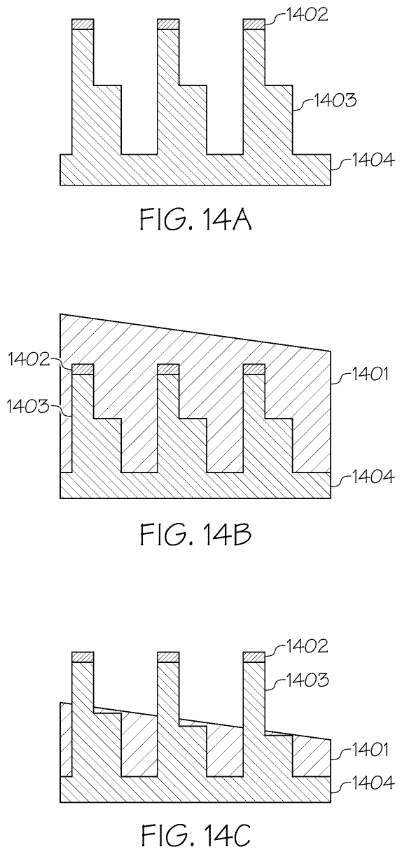

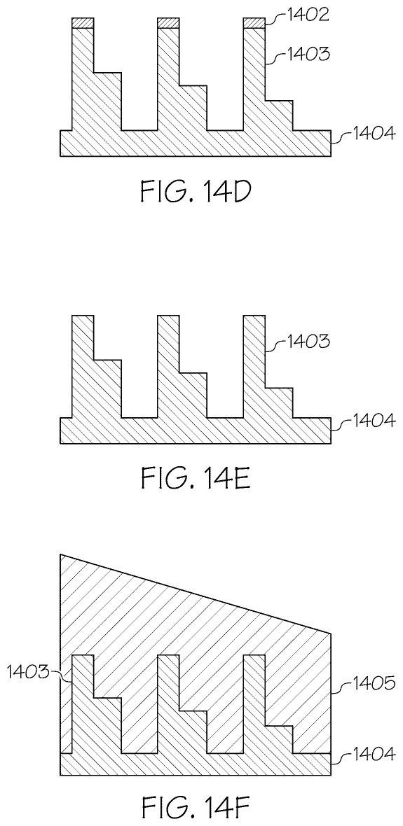

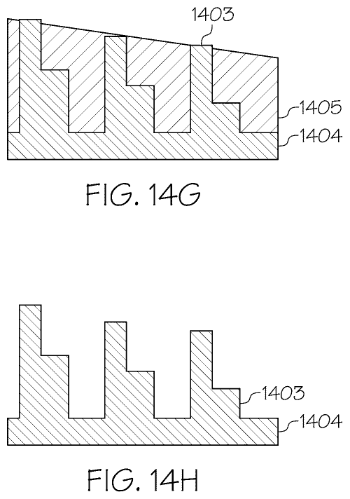

FIG. 13 is a flowchart of a method 1300 for fabricating the MMGTD with an initial mask in accordance with an embodiment of the present disclosure. FIGS. 14A-14H depict the cross-sectional views fabricating the MMGTD with an initial mask using the steps described in FIG. 13 in accordance with an embodiment of the present disclosure.

Referring to FIG. 13, in conjunction with FIGS. 14A-14H, in step 1301, a polymer 1401 is deposited on the initial hard mask 1402 as well as on pattern 1403 and substrate 1404 made of inorganic material, such as fused silica, using the nP3 process for profiling the lower step (slope 1) as shown in FIGS. 14A and 14B. FIG. 14A illustrates the MMGTD with the initial hard mask protecting the top-most tier while FIG. 14B illustrates the deposition of polymer 1401 on MMGTD. In one embodiment, hard mask 1402 includes one or more of the following materials, such as Cr, CrO, CrON, MoSiO, MoSiON, CrF, SiN, CrN, CrOCN, SiCrO, WSi and ZrSiO.

In one embodiment, polymer 1401 is deposited with a spatial gradient consistent with the desired gradient in the next tier.

In step 1302, a portion of polymer 1401 is removed, such as via an anisotropic etch and oxidation-based removal or ashing of polymer 1401, as shown in FIG. 14C. In such a removal, the top portions of the bottom tiers of pattern 1403 are removed in a downward slanted direction corresponding to slope 1.

In step 1303, an anisotropic matched etch of polymer 1401 and pattern 1403 is performed to create a spatial gradient in the bottom tier without affecting the top tier as shown in FIG. 14D.

In step 1304, hard mask 1402 is removed, such as via wet stripping, as shown in FIG. 14E. That is, hard mask 1402 on the top tier of pattern 1403 is stripped.

In one embodiment, steps 1301-1304 are repeated until the desired gradient in the top tier is achieved. In one embodiment, if there are more than two tiers, hard mask 1402 is not stripped. Rather, as described in method 1100, prior to the ashing of polymer 1401, a hard mask (e.g., metals, oxides, nitrides, etc.) is deposited using the selective ALD on the exposed fused silica. Then, the polymer material is removed and subsequent lower tiers are profiled iteratively. After all the lower tiers have been graded, the hard masks are stripped, leaving only the topmost tier without being graded. A subsequent nP3, etch and polymer ash iteration is then conducted for the topmost tier.

In step 1305, a polymer 1405 is deposited on pattern 1403 and substrate 1404 using the nP3 process for profiling the upper step (slope 2) as shown in FIG. 14F.

In step 1306, an anisotropic matched etch of polymer 1405 and pattern 1403 is performed to create a spatial gradient in the top tier as shown in FIG. 14G. In such a removal, the top portions of the top tiers of pattern 1403 are removed in a downward slanted direction corresponding to slope 2.

In step 1307, polymer 1405 as well as a portion of the top tiers of pattern 1403 are removed, such as via ashing, as shown in FIG. 14H.

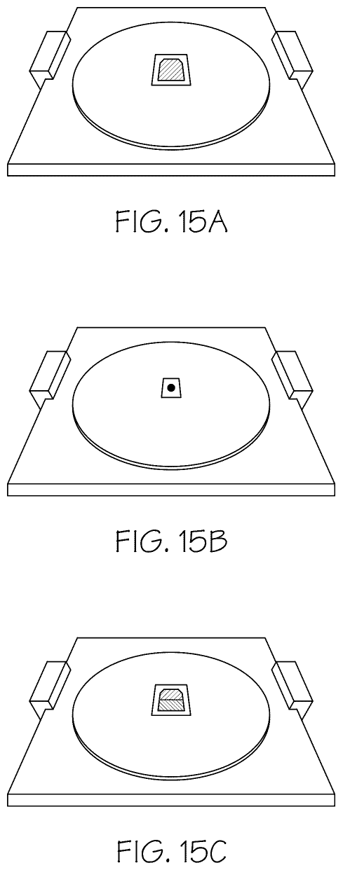

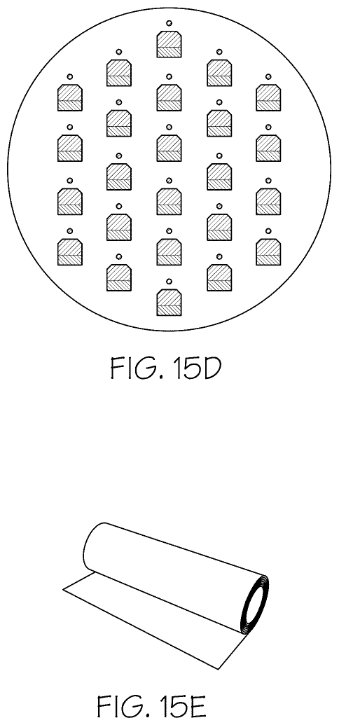

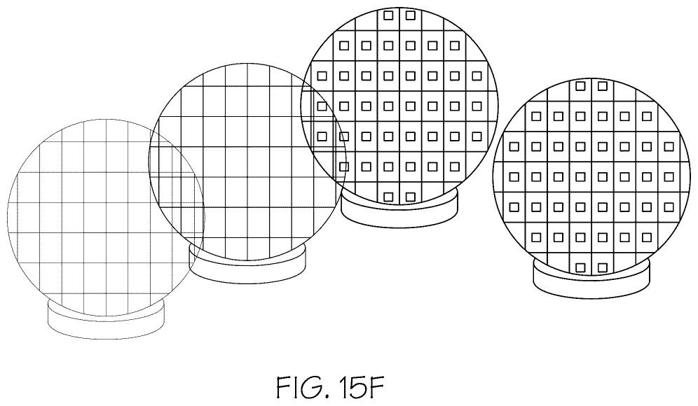

FIGS. 15A-15F illustrate the overall fabrication process of high-refractive index multi-graded depth inorganic waveguides (HMIWs) on high-index wafers in accordance with an embodiment of the present disclosure. In one embodiment, the diameter of the wafers are 300 mm. In one embodiment, the refractive index of the wafers is >1.5. FIG. 15A illustrates a multi-tiered, uniform depth master output grating (MUM-OG). FIG. 15B illustrates a multi-tiered, uniform depth master input grating (MUM-IG). FIG. 15C illustrates a multi-tiered, multi-graded depth master with output grating (MMM-OG). FIG. 15D illustrates a multi-tiered, multi-graded super-master (MMS). FIG. 15E illustrates a multi-tiered, multi-graded working template consisting of nanoscale patterns, such as input gratings and output gratings. FIG. 15F illustrates high-index, multi-graded depth inorganic waveguides.

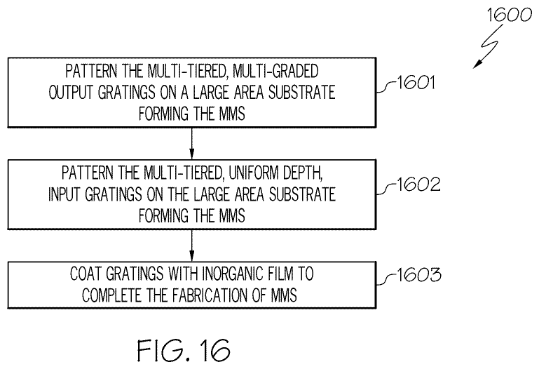

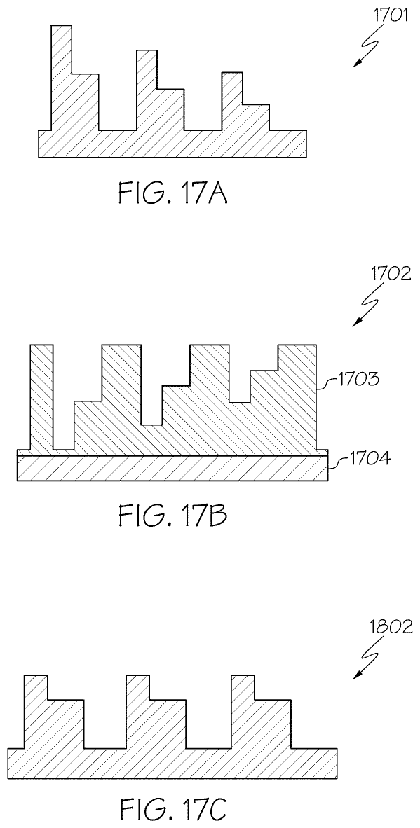

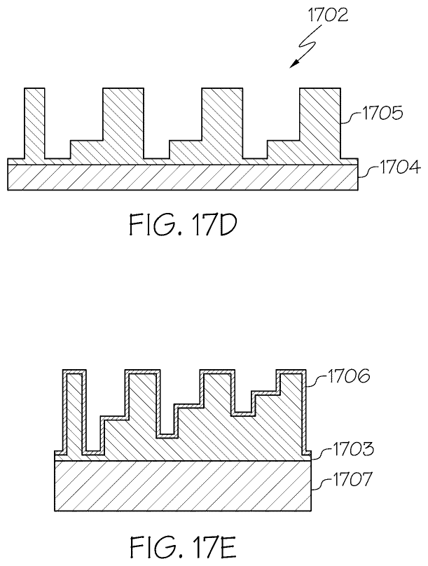

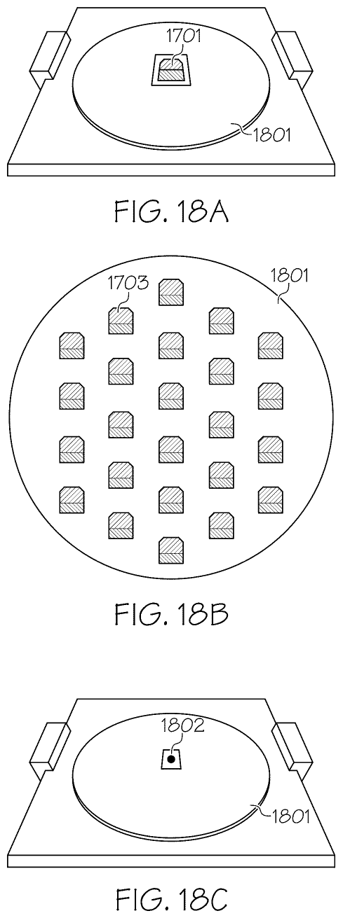

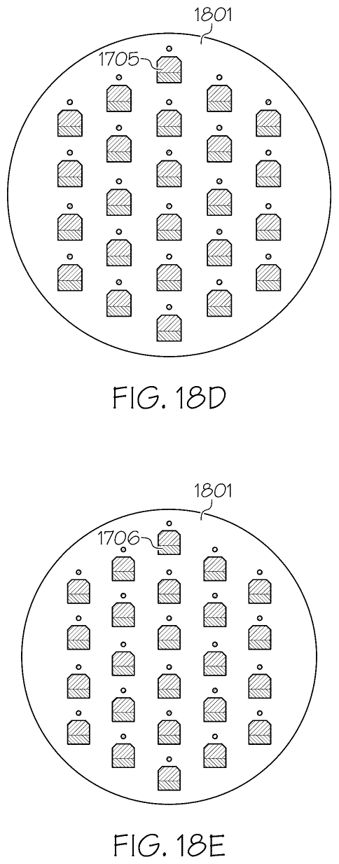

FIG. 16 is a flowchart of a method 1600 for fabricating a multi-tiered, multi-graded super-master (MMS) in accordance with an embodiment of the present disclosure. FIGS. 17A-17E depict the cross-sectional views for fabricating a multi-tiered, multi-graded super-master (MMS) using the steps described in FIG. 16 in accordance with an embodiment of the present disclosure. FIGS. 18A-18E depict images of structures in connection with method 1600 in accordance with an embodiment of the present disclosure.

Referring to FIG. 16, in conjunction with FIGS. 17A-17E and 18A-18E, in step 1601, the multi-tiered, multi-graded output gratings 1703 on a large area substrate are patterned forming the MMS. In particular, the output gratings 1703 of super master 1702 are patterned for MMS using multi-tiered uniform depth master 1701 with output gratings as shown in FIGS. 17A and 17B. In one embodiment, multi-tiered uniform depth master 1701 has a pattern with a positive tone in fused silica. FIG. 18A illustrates multi-tiered uniform depth master 1701 on wafer 1801.

In one embodiment, output gratings 1703 has the pattern of a negative tone as shown in FIG. 17B. In one embodiment, such a pattern (pattern of output gratings 1703) is fabricated using e-beam lithography, photolithography or other patterning techniques.

In one embodiment, a copy of multi-tiered uniform depth master 1701 is made forming “super master” 1702 with multiple fields. In one embodiment, super master 1702 is formed via the use of step-and-repeat nanoimprint lithography across the substrate of multi-tiered uniform depth master 1701.

FIG. 17B further illustrates a layer of resist on silicon 1704 of super master 1702. In one embodiment, nanoimprint lithography super master 1702 has nanopatterns with multiple tiers. An illustration of the multiple output gratings 1703 on wafer 1801 is depicted in FIG. 18B.

In step 1602, the multi-tiered, uniform depth, input gratings 1705 on the large area substrate are patterned forming the MMS. In particular, the input gratings 1705 of intermediate master template (super master 1702) are patterned using a single-field input grating template 1802 as shown in FIGS. 17C and 17D. In one embodiment, such a pattern of input gratings 1705 has a negative tone.

FIG. 17C illustrates a single-field input grating template 1802 with a positive tone. In one embodiment, the material of single-field input grating template 1802 is fused silica.

FIG. 18C is an image of single-field input grating template 1802 on wafer 1801.

FIG. 17D illustrates a layer of resist on silicon 1704 of super master 1702. In one embodiment, nanoimprint lithography super master 1702 has nanopatterns with multiple tiers. An illustration of the multiple input gratings 1705 on wafer 1801 is depicted in FIG. 18D.

In step 1603, the gratings (resist) 1703 is coated with inorganic film 1706 to complete the fabrication of MMS as shown in FIGS. 17E and 18E. As shown in FIG. 17E, the substrate now corresponds to a resist on silicon with thin inorganic coating 1707. Furthermore, the pattern of output gratings 1703 has a negative tone. FIG. 18E illustrates output gratings 1703 coated with inorganic film 1706 on wafer 1801.

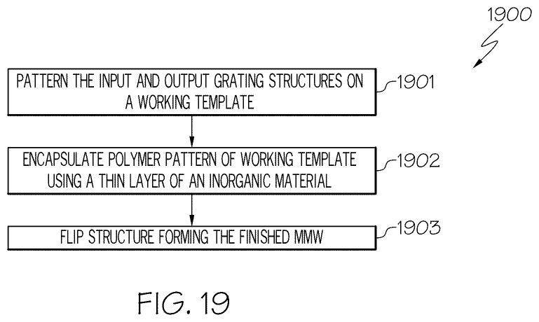

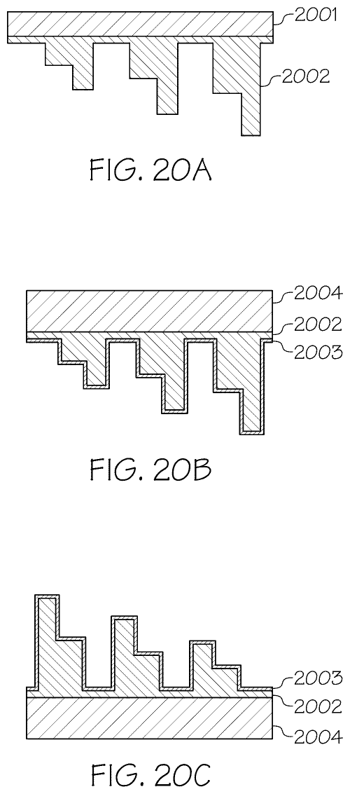

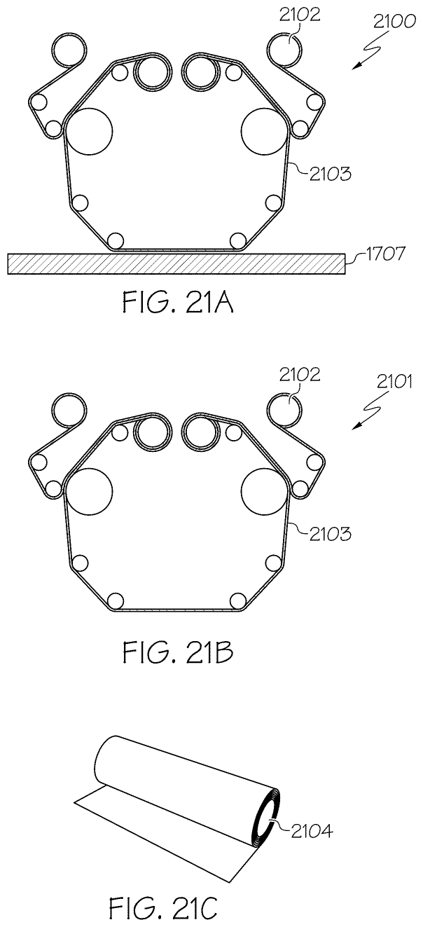

Referring now to FIG. 19, FIG. 19 is a flowchart of a method 1900 for fabricating a multi-tiered, multi-graded working template (MMW) in accordance with an embodiment of the present disclosure. FIGS. 20A-20C depict the cross-sectional views for fabricating a multi-tiered, multi-graded working template (MMW) using the steps described in FIG. 19 in accordance with an embodiment of the present disclosure. FIGS. 21A-21B depict the web handling module 2101 for handling the web and FIG. 21C illustrates the resulting web using the steps described in FIG. 19 in accordance with an embodiment of the present disclosure.

In one embodiment, MMW is used to transfer patterns on a substantially rigid substrate (e.g., Si, SiO₂) or a substantially flexible web (polycarbonate or polyethylene terephthalate). The patterned substrate is then encapsulated with inorganic material as discussed further below.

Referring to FIG. 19, in conjunction with FIGS. 20A-20C and 21A-21C, in step 1901, the nanoscale pattern including input and output grating structures 2002 (also referred to herein as “polymer pattern” 2002) of the web are patterned on a working template 2001 using the structure shown in FIGS. 17E and 18E. An illustration of such patterning is shown in FIGS. 20A and 21A. In one embodiment, working template 2001 corresponds to the resist on the polycarbonate (PC) web. FIG. 21A illustrates a web handling module 2101 consisting of unwind and rewind rollers 2102 to pattern super master 1707 on working template 2001 using web 2103. In one embodiment, polymer pattern 2002 of working template 2001 has a positive tone.

In step 1902, polymer pattern 2002 (resist structures consisting of input and output grating structures) of working template 2001 is encapsulated using a thin (<20 nm) layer of an inorganic material 2003, such as Au, SiO₂ and Si₃N₄, which can be deposited using PVD or low-temperature CVD techniques, where the substrate (working template) 2004 now includes the polymer replica with the thin inorganic coating on the polycarbonate. In one embodiment, such an encapsulation is performed using the web handling module 2101 of FIG. 21B. In one embodiment, polymer pattern 2002 encapsulated with inorganic material 2003 has a positive tone.

In step 1903, in one embodiment, the structure shown in FIG. 20B consisting of pattern 2002 encapsulated with inorganic material 2003 on working template 2004 is flipped forming the finished MMW as shown in FIG. 20C. The resulting polycarbonate web 2104 is depicted in FIG. 21C, which is now available for use. In one embodiment, the pattern of the finished MMW has a positive tone.

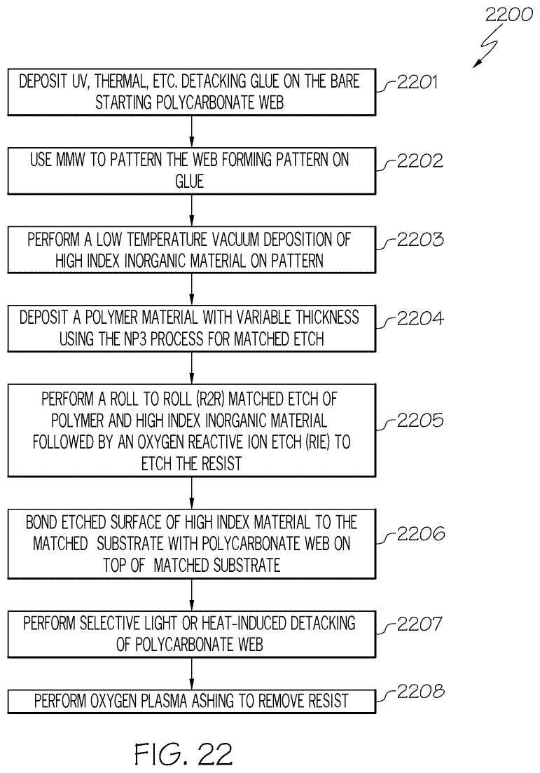

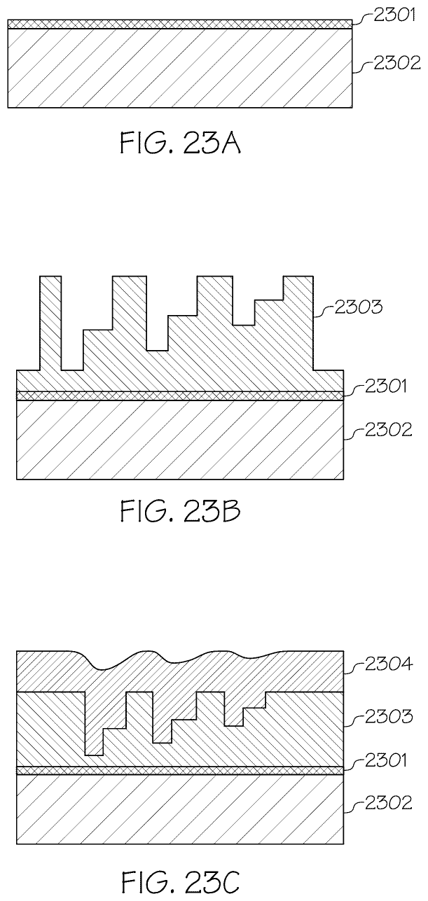

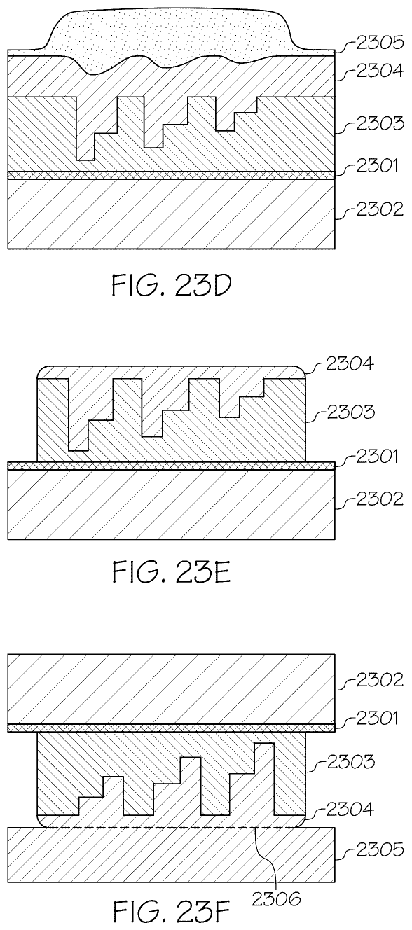

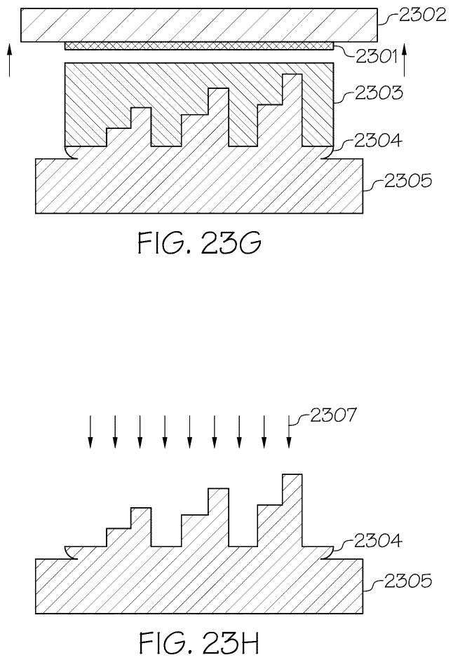

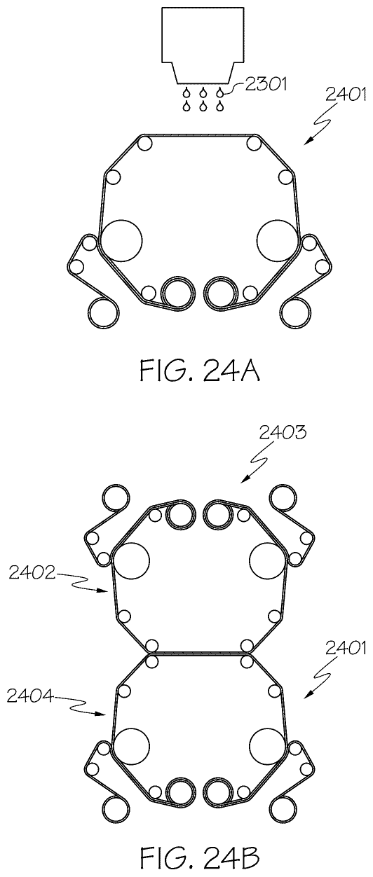

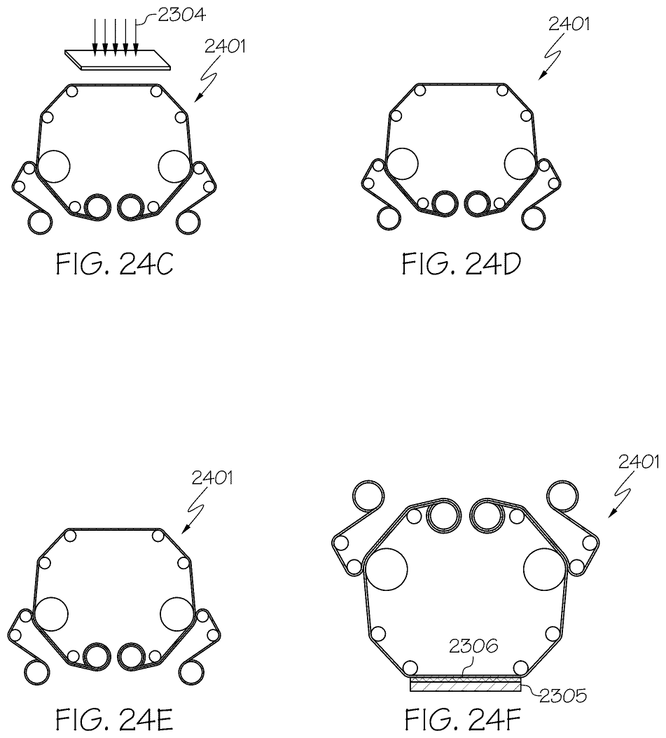

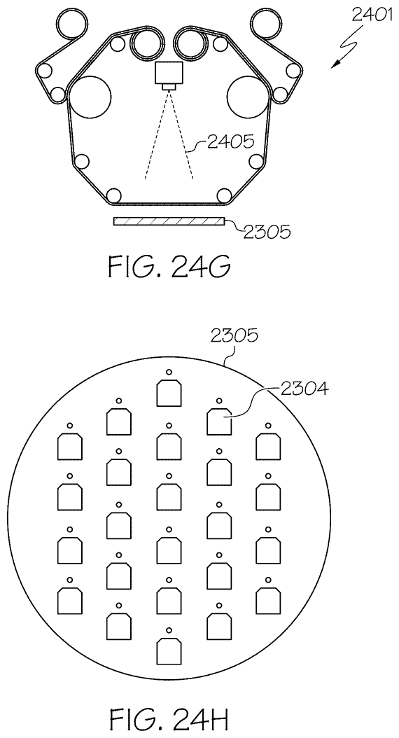

Referring now to FIG. 22, FIG. 22 is a flowchart of a method 2200 for fabricating a high-index multi-graded depth inorganic waveguide (HMMW) on high-index wafers in accordance with an embodiment of the present disclosure. In one embodiment, the diameter of the wafers is 300 mm. In one embodiment, the refractive index of the wafers is >1.5. FIGS. 23A-23H depict the cross-sectional views for fabricating a high-index multi-graded depth inorganic waveguide (HMMW) on high-index wafers using the steps described in FIG. 22 in accordance with an embodiment of the present disclosure. FIGS. 24A-24H depict the utilization of the web handling module for fabricating the HMMW in accordance with an embodiment of the present disclosure.

Referring to FIG. 22, in conjunction with FIGS. 23A-23H and 24A-24H, in step 2201, UV, thermal, etc. detacking glue 2301 (e.g., light switchable adhesive) is deposited on the bare starting polycarbonate web 2302 (working template) as shown in FIG. 23A. FIG. 24A illustrates web handling module 2401 for depositing glue 2301 on bare starting polycarbonate web 2302.

In step 2202, a MMW is used to pattern the web forming pattern 2303 on glue 2301 as shown in FIG. 23B. In one embodiment, pattern 2303 has a negative tone. FIG. 24B illustrates MMW 2402 of web handling module 2403 as well as the web 2404 patterned with MMW using web handling module 2401.

In step 2203, the vacuum deposition of high index inorganic material 2304 (e.g., oxide/nitride material) on pattern 2303 is performed as shown in FIG. 23C. In one embodiment, pattern 2303 has a negative tone. FIG. 24C illustrates the vacuum deposition of inorganic material 2304 on pattern 2303 using web handling module 2401. In one embodiment, inorganic material 2304 consists of oxides, nitrides and carbides. In one embodiment, the vacuum deposition of inorganic material 2304 is performed at a temperature of <200° C.

In step 2204, polymer material 2305 with variable thickness is deposited using the nP3 process for matched etch as shown in FIG. 23D. A discussion regarding the nP3 process is provided in International Application No. PCT/US2021/019732, which is incorporated by reference herein in its entirety. FIG. 24D illustrates web handling module 2401 for performing such a deposition.

In step 2205, a roll to roll (R2R) etch of polymer/inorganic material 2304 (e.g., polymer/oxide, polymer/nitride) followed by an oxygen reactive ion etch (RIE) to etch the resist is performed resulting in the structure shown in FIG. 23E. FIG. 24E illustrates web handling module 2401 for performing such an operation. In one embodiment, the etch of polymer/inorganic material 2304 is substantially matched.

In step 2206, inorganic material 2304 is bonded to the matched substrate 2305 with polycarbonate web 2306 on top of matched substrate 2305 as shown in FIG. 23F. FIG. 24F illustrates web handling module 2401 for performing such an operation.

In step 2207, selective light or heat-induced detacking of the polycarbonate web 2306 is performed forming the structure as shown in FIG. 23G. FIG. 24G illustrates web handling module 2401 for performing such an operation using light or heat 2405.

In step 2208, oxygen plasma ashing 2307 is performed to remove resist 2303 as shown in FIG. 23H. In one embodiment, such a pattern (see element 2304) has a positive tone on the matched substrate 2305 (e.g., fused silica). The resulting structure of pattern 2304 on matched substrate 2305 is depicted in FIG. 24H.

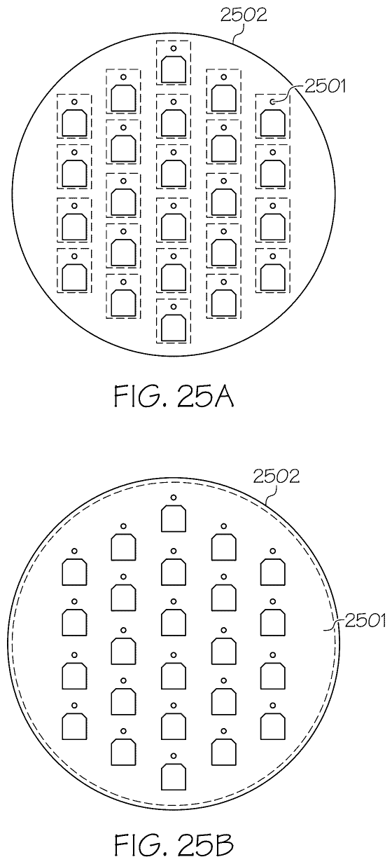

Referring now to FIGS. 25A-25B, FIGS. 25A-25B illustrate HMIW options for coverage of high index material bonded to a 300 mm wafer in accordance with an embodiment of the present disclosure. FIG. 25A illustrates multiple fields of high index material 2501 on wafer 2502. FIG. 25B illustrates coverage of high index material 2501 over the entire wafer 2502.

In FIGS. 22, 23A-23H, 24A-24H and 25A-25B, a process is described to fabricate high-index multi-graded depth inorganic waveguides on 300 mm wafers. A UV detacking adhesive is deposited on a bare PC web. The UV detacking adhesive whose adhesive strength can be increased or decreased by applying heat or light. UV exposure of a specific dosage is shown to liquefy these light switchable adhesives and thereby lowering the adhesion strength significantly (i.e., detacking). These light switchable adhesives can be transformed to its high adhesion strength state through exposure with visible light of a specific dosage. In FIG. 24A, the UV detacking adhesive is deposited and transformed to its high adhesion strength state. A layer of imprint resist is then deposited and patterned using the MMW (multi-tiered, multi-graded working) template. Upon UV curing and separation, solidified resist patterns with negative tone remains on the PC web. It is noted that the UV dosage for curing resist in the patterning step is significantly different from the UV dosage required to convert the UV detacking adhesive into a liquid. This helps ensure that the UV detacking adhesive layer remains intact in the patterning step. In one embodiment, the patterned resist is then dry ashed for a limited time to eliminate the top layer (a couple of nm) that contains a surfactant inhibiting adhesion, thereby increasing the surface energy of the patterned resist layer. The functional material is deposited into the negative tone patterned layer via vacuum deposition. The functional material is typically an inorganic high refractive index material (>1.6) that contains Si, Ti or Ga. The nP3 process is performed on the deposited functional material followed by etch back. This leads to a planarized layer of functional material. A wafer with a substantially matching refractive index with respect to the functional material is bonded to this planar layer. In one embodiment, direct bonding between oxide layers can be used here. In one embodiment, direct bonding corresponds to fusion bonding of oxide to oxide or anodic bonding. In one embodiment, using a polymer film between the functional material wafer and the functional material planar later can improve strain relief. Once bonding is complete, the UV detacking adhesive layer is converted to its low adhesion strength form (liquefied). The PC web is separated at the UV detacking adhesive layer. Finally, the polymer resist is dry ashed away and the high index material with multi-tiered multi-graded depth patterns remain on the wafer. It is noted that the fabrication of HMIWs can also be performed on substantially flat substrates (e.g., Si or SiO₂) instead of flexible webs (e.g., PC or PET). In the above fabrication process of high-index multi-graded depth inorganic waveguides (HMIWs) and multi-graded, uniform-depth, granddaughter template (MUGDT), a conventional adhesive could be used instead of a UV detacking adhesive. In one embodiment, the conventional adhesive is deposited using inkjets to generate a contiguous adhesive layer. An exemplar adhesive used for bonding at the interface of the inorganic materials is TranSpin manufactured by Canon Nanotechnologies or mr-APS1* manufactured by Microresist. The adhesion strength of the conventional adhesive in this case would be significantly lower than the bonding strength at the interface between the high index inorganic material and the high index inorganic substrate. This can allow detacking at the conventional adhesive interface without any unwanted delamination at the bonded interface. Examples of weak conventional adhesives include silane adhesives, such as allyl methyl dichloro silane or bottom anti-reflective coatings (BARC). In FIGS. 9D and 23D, in one embodiment, deposition of polymer material for the matched etch is followed by a patterning step before undergoing the matched etch step. The patterns created can have pitches between 25 nm and 1 micrometers. Exemplar patterns include nanoscale and microscale moth eye structures. The deposited resist with the aforementioned patterns is then etched into the inorganic high index material. In one embodiment, the bonding step as shown in FIGS. 9F and 23F is performed by using a conventional adhesive, such as UV curable adhesive. In one embodiment, the bonding process discussed in the fabrication of MUGDT and HMIWs can be applied at an interface comprising of any 2 of the following materials: silicon dioxide, silicon nitride or silicon carbide. In one embodiment, silicon nitride is bonded to silicon or silicon dioxide by using spin on glass as an adhesive. In one embodiment, silicon nitride is bonded to silicon nitride via oxidation in wet oxygen at 1100° C. For a low temperature bonding process of silicon nitride to glass, silicon nitride and glass are first plasma treated and exposed to air. The surfaces are then brought into contact which forms hydrogen bonds. Removal of water molecules leads to strong Si—O—Si covalent bond formation. Low temperature (300° C.-400° C.) bonding between silicon nitride surfaces and room temperature bonding between silicon nitride and silicon dioxide has been demonstrated.

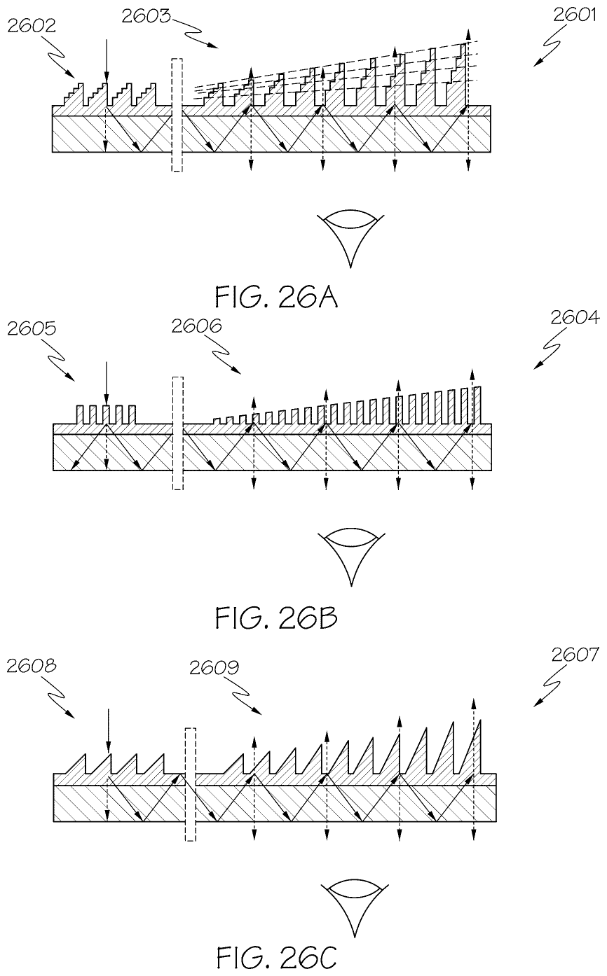

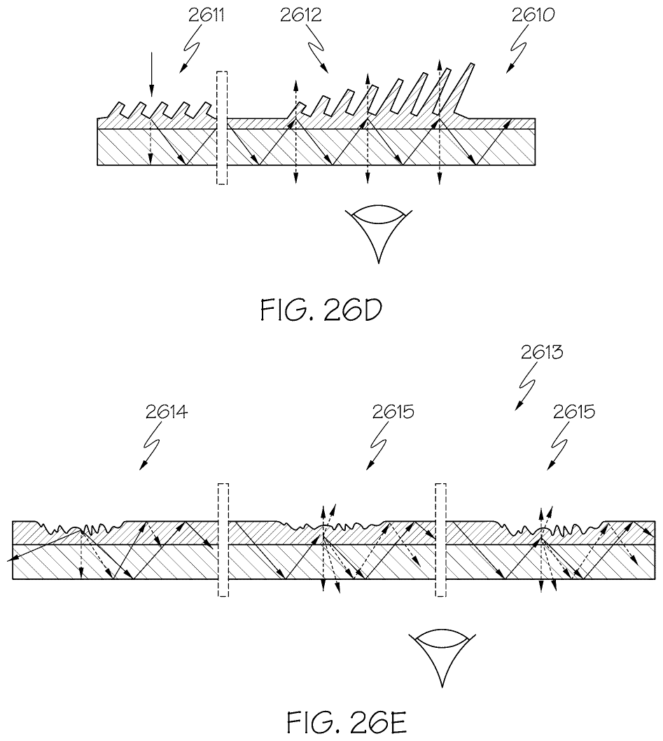

Various patterns can be included in the templates used to fabricate the aforementioned optical elements. The template types are illustrated in FIGS. 26A-26E.

FIGS. 26A-26E illustrate various template types in accordance with an embodiment of the present invention.

Referring to FIG. 26A, FIG. 26A illustrates a multi-tiered, multi-graded template 2601 using the fabrication steps discussed above. FIG. 26A further illustrates the input image 2602 and the image 2603 seen by the viewer.

FIG. 26B illustrates a single-tiered, multi-graded template 2604. This is a subset of the multi-tiered, multi-graded template. A single nP3 step is used to fabricate this template. FIG. 26B further illustrates the input image 2605 and the image 2606 seen by the viewer.

FIG. 26C illustrates a template 2607 with multi-graded blazed gratings. In one embodiment, greyscale e-beam lithography in combination with the nP3 process are used to fabricate templates with these structures. FIG. 26C further illustrates the input image 2608 and the image 2609 seen by the viewer.

FIG. 26D illustrates a template 2610 with multi-graded slanted gratings. In one embodiment, focused ion beam fabrication in combination with the nP3 process are used to fabricate templates with these structures. FIG. 26D further illustrates the input image 2611 and the image 2612 seen by the viewer.

FIG. 26E illustrates a template 2613 with analog/digital surface relief gratings (computer generated holograms). For template types 2607, 2610 and 2613, additive manufacturing methods, such as parallelized two-photon lithography and computed axial lithography, are used. Holographic components can also be fabricated by creating interference patterns on a photosensitive substrate. FIG. 26E further illustrates an input image 2614 and an image 2615 seen by the viewer.

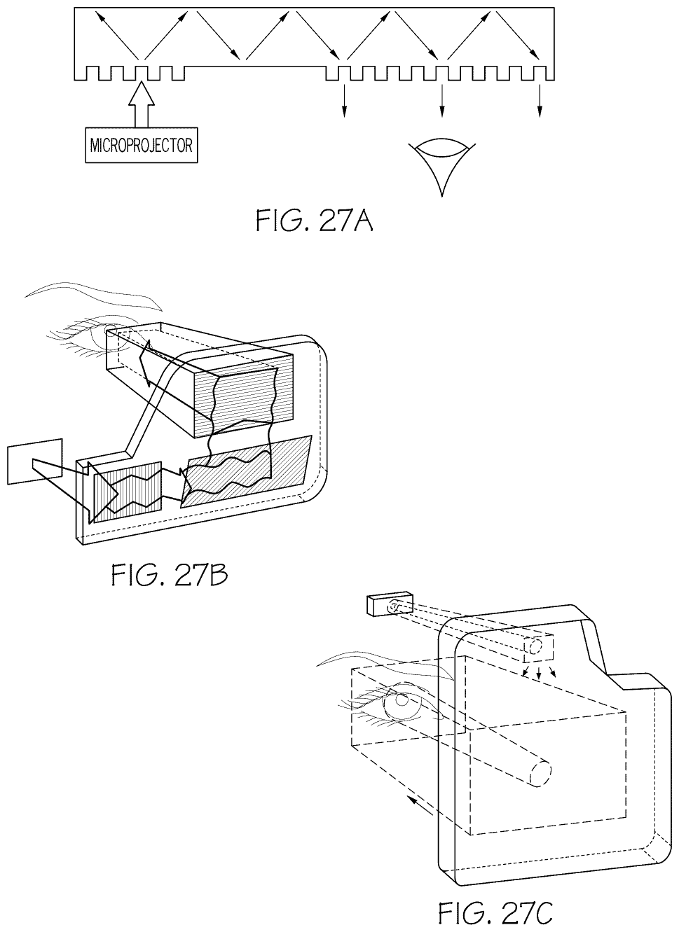

FIGS. 27A-27C illustrate exit pupil expansion (EPE) in diffraction grating in accordance with an embodiment of the present disclosure. FIG. 27A illustrates a one-dimensional EPE illustration. FIG. 27B illustrates a two-dimensional EPE using turn grating. FIG. 27C illustrates a two-dimensional EPE using two-dimensional grating.

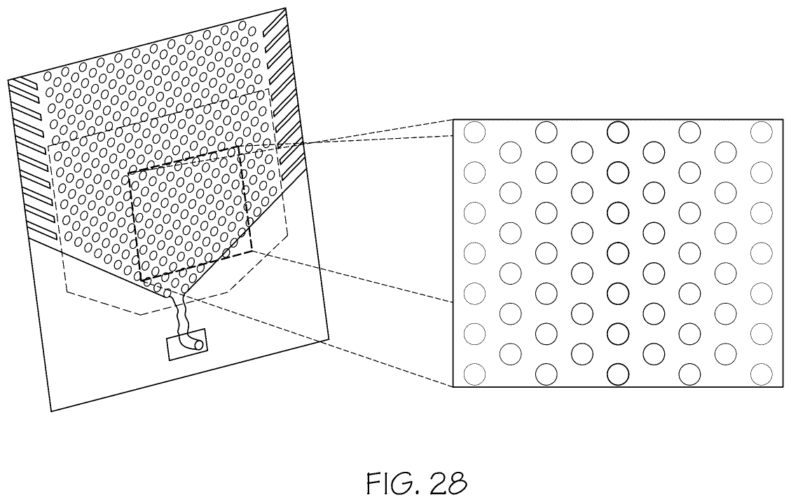

FIG. 28 illustrates a lightguide with two-dimensional periodic grating structures (diamond-shaped) in accordance with an embodiment of the present disclosure.

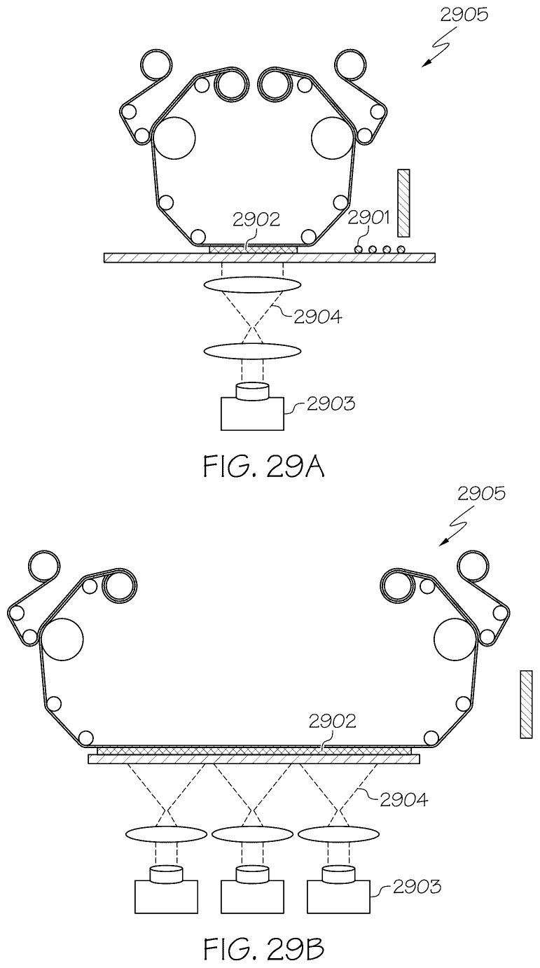

FIGS. 29A-29B illustrate an exemplary manufacturing system architecture for fabricating customized beam splitting gratings for applications, such as facial recognition, in accordance with an embodiment of the present disclosure. FIG. 29A illustrates a high volume roll template used to fabricate nanostructures on a substrate and producing multi-graded features using an inkjet based deposition subsystem and a pixelated thermal input. FIG. 29B illustrates a high throughput system architecture with parallel fabrication of multi-graded nanostructures.

FIGS. 29A-29B illustrate an exemplar system for fabricating customized diffractive optical elements using a web handling module 2905. These optical elements can be used in applications, such as facial recognition in smart phones and security related features. A polymer resist 2901 is deposited using an inkjet based sub-system or slot die coater or gravure coater or a combination of them. The substrate 2902 on which the nanostructures for diffractive optical clements are fabricated can be glass sheets of sizes, such as 1×1 m or 0.5×0.5 m, or others. In one embodiment, substrate 2902 on which the nanostructures for diffractive optical elements are fabricated consists of polymer sheets, such as sizes of 1×1 m or 0.5×0.5 m, or other, or rolls of width, such as 1 m or 0.5 m, or others. The template used to transfer patterns can be a single field master template or a multi-field large area template or a high volume roll template. Typical device sizes for customized diffractive optical elements are 2×2 mm or 4×4 mm or others. The manufacturing system also includes a projector 2903 for irradiating a customized pixelated heat pattern via light beams 2904 on the device area. In one embodiment, such irradiation is performed via the use of Digital Micromirror Devices (DMDs). Furthermore, in one embodiment, a stream of time-varying, high resolution custom heat profiles are irradiated on the device area. In one embodiment, the pixels on the projector device 2903 are digitally controlled to produce millions of custom heat profiles. In one embodiment, these profiles are used to produce multi-graded nanostructures with a custom profile for each device. In one embodiment, a multi-graded diffractive optical device generates a dot pattern with spatially varying intensity profiles that improve facial recognition functionalities. The inkjet based polymer deposition sub-system can also be programmed to create custom profiles. FIG. 29A illustrates a manufacturing system with a single projector 2903 irradiating collimated light beams 2904 on the device area. FIG. 29B illustrates a high throughout with an array of projectors 2903 irradiating a custom heat profile via light beams 2904 over multiple devices in parallel.

FIGS. 30A-30B illustrate the steps for fabricating a high volume template for applications, such as facial recognition, in accordance with an embodiment of the present disclosure. FIG. 30A illustrates a master template 3001 from an exemplary material, such as fused silica. FIG. 30B illustrates an exemplary high volume roll template 3002 made by replicating patterns from master template 3001.

FIG. 30A illustrates a typical master template 3001 with a single-depth nanostructure pattern and variable pitch and feature sizes. In one embodiment, master template 3001 is fabricated in silicon or fused silica or others. In one embodiment, master template 3001 is used to produce a large area multi-field template via techniques, such as nanoimprint lithography. The polymer patterns in the large area template are encapsulated with inorganic materials, such as silicon dioxide, or the polymer patterns can be etched into silicon or fused silica substrate. FIG. 30B illustrates how the large area, multi-field template is used to produce a high volume roll template 3002 via plate-to-roll nanoimprint lithography. The polymer patterns on the flexible substrate are encapsulated with inorganic materials, such as silicon dioxide and others.

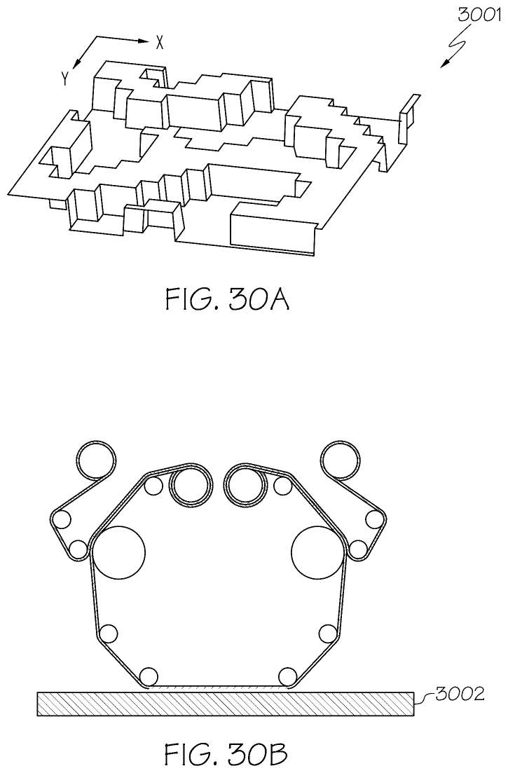

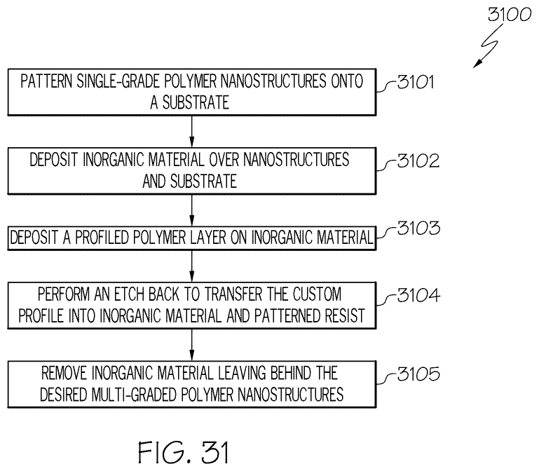

FIG. 31 is a flowchart of a method 3100 for fabricating polymer nanostructures with customized multi-graded features in accordance with an embodiment of the present disclosure. FIGS. 32A-32E depict the cross-sectional views for fabricating polymer nanostructures with customized multi-graded features using the steps described in FIG. 31 in accordance with an embodiment of the present disclosure.

Referring to FIG. 31, in conjunction with FIGS. 32A-32E, in step 3101, single-grade polymer nanostructures 3201 are patterned onto a substrate 3202 as shown in FIG. 32A.

In step 3102, inorganic material 3203 is deposited over nanostructures 3201 and substrate 3202, such as via vacuum deposition, as shown in FIG. 32B. In one embodiment, inorganic material 3203 corresponds to SiO₂.

In step 3103, a profiled polymer layer 3204 is deposited on inorganic material 3203 as shown in FIG. 32C. Furthermore, polymer layer 3204 is customed profiled.

In step 3104, an etch back is performed to transfer the custom profile into inorganic material 3203 and patterned resist (nanostructures) 3201 as shown in FIG. 32D.

In step 3105, inorganic material 3203 is removed leaving behind the desired multi-graded polymer nanostructures 3201 as shown in FIG. 32E. In one embodiment, an HF etch is performed to remove the inorganic material 3203 (e.g., SiO₂) in the trenches to leave the customized polymer resist patterns (patterns of nanostructures 3201).

FIGS. 31 and 32A-32E illustrate that a high volume roll template from FIG. 30B (or a single field master template) can be used to produce diffractive optical elements with polymer nanostructures and a customized gradient profile for every device. In FIG. 32A, the template is used to transfer polymer patterns on the substrate (e.g., substrate 3202). In one embodiment, substrate 3202 comprises glass or a polymer, including PC, PET, PEB or others. In one embodiment, PVD of reflective material, such as Al, is performed for applications, such as diffractive optical elements that are reflective in nature. In one embodiment, the polymer is deposited via inkjets or slot die coating or gravure coating or a combination of them. FIG. 32B illustrates vacuum deposition of inorganic material 3203 on the polymer nanostructures 3202. In one embodiment, vacuum deposition is performed via Plasma Enhanced Chemical Vapor Deposition (PECVD) at temperatures below 100° C. or 150° C. Materials deposited can be silicon dioxide, silicon nitride and others. FIG. 32C illustrates a profiling polymer material 3204 deposited on inorganic layer 3203. In one embodiment, profiling polymer layer 3204 is deposited via inkjets or slot die coating or gravure coating or a combination of them. The custom profiling of profiling polymer 3204 is performed via custom inkjet drop patterns or projection of heat pattern or both. A matched etch is performed to etch the profiled layer of polymer 3204 into inorganic layer 3203 and the patterned polymer layer 3204 as shown in FIG. 32D. This etch-back of polymer 3204 into the inorganic film 3203 and polymer nanostructures 3202 can be achieved through dry etching in a plasma. Different etch chamber configurations can be used, including capacitively coupled plasma chambers (i.e., a parallel plate configuration), CCP, or inductively coupled plasma chambers, ICP. In one embodiment, the etch rates of polymer 3204 and inorganic material 3203 are controlled by adjusting the parameters of the etch process. Adjustable etch parameters include the process pressure (1 mTorr-1000 mTorr), gas flow rates (0.1-100 sccm), applied RF power (20 W-400 W), RF frequency (2-100 MHz), substrate temperature (−150° C. to 400° C.), gas chemistry (Ar, CF₄, CHF₃, O₂, SF₆, Cl₂, HBr, C₄F₈, H₂, He, N₂), and DC bias (5V-1000V) across the electrodes. In the ICP etch chamber configuration, the ICP power (20 W-2500 W) is an additional process parameter that can be tuned. In general, different combinations of the parameter set can yield etch selectivity, polymer: inorganic layer, in the range 0.1 to 10 where polymer: inorganic layer etch selectivity of <1 leads to pattern amplitude magnification, polymer: inorganic layer etch selectivity of >1 leads to pattern amplitude reduction, and polymer: inorganic layer etch selectivity that =1 leads to pattern amplitude replication. In FIG. 32E, inorganic material 3203 is removed via selective chemical etching to leave behind the custom profiled multi-graded polymer nanostructures 3202. Hydrofluoric acid is an exemplar material used to remove inorganic material 3203 (e.g., silicon dioxide).

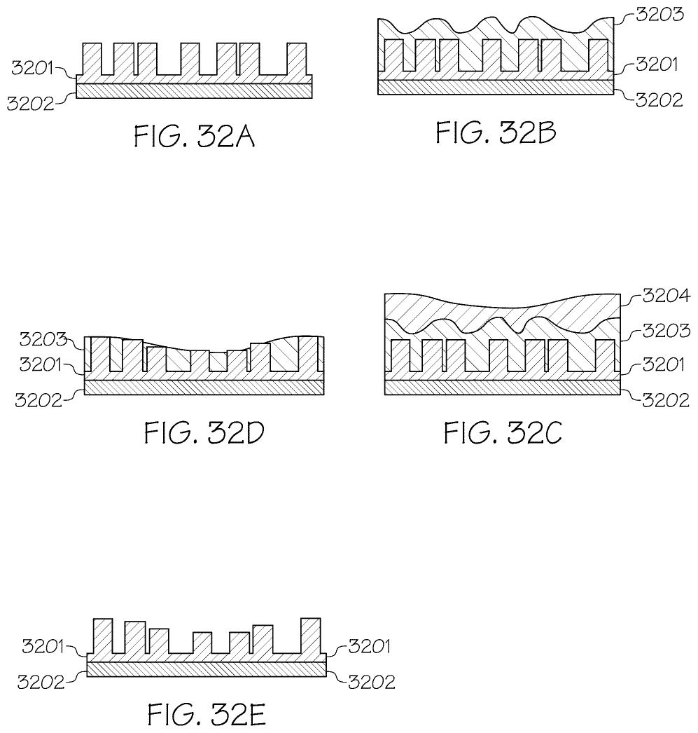

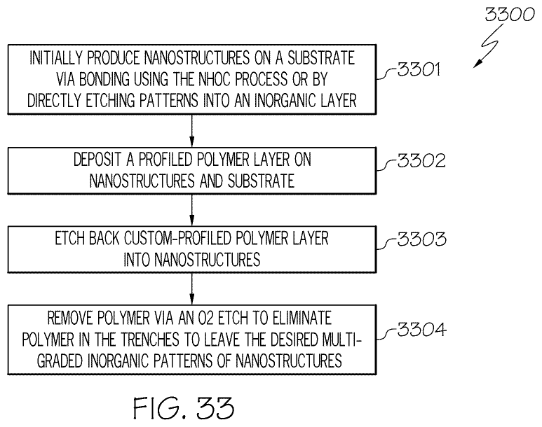

FIG. 33 is a flowchart of a method 3300 for fabricating inorganic nanostructures with customized multi-graded features in accordance with an embodiment of the present disclosure. FIGS. 34A-34D depict the cross-sectional views for fabricating inorganic nanostructures with customized multi-graded features using the steps described in FIG. 33 in accordance with an embodiment of the present disclosure.

Referring to FIG. 33, in conjunction with FIGS. 34A-34D, in step 3301, nanostructures 3401 of inorganic materials on a substrate 3402 are initially produced via bonding using the nHOC process of the present disclosure or by directly etching patterns into an inorganic layer as shown in FIG. 34A. The pattern of nanostructures 3401 is a positive tone.

In step 3302, a profiled polymer layer 3403 is deposited on nanostructures 3401 and substrate 3402 as shown in FIG. 34B. In one embodiment, polymer layer 3403 is custom profiled.

In step 3303, a custom-profiled polymer layer 3403 is etched back into nanostructures 3401 as shown in FIG. 34C. In one embodiment, such an etch back achieves the custom multi-graded inorganic pattern, where the trenches are filled with polymer 3403.

In step 3304, polymer 3403 is removed via an O₂ etch to eliminate polymer 3403 in the trenches to leave the desired multi-graded inorganic patterns of nanostructures 3401.

FIGS. 33 and 34A-34D are directed to the fabrication steps that can be used to produce diffractive optical elements with inorganic nanostructures and a customized gradient profile for every device. FIG. 34A starts with a single-depth inorganic nanostructure 3401 produced via the fabrication steps discussed above in FIGS. 23A-23H while using the template shown in FIGS. 30A-30B. FIG. 34B illustrates a profiling polymer material 3403 deposited on inorganic nanostructures 3401. In one embodiment, profiling polymer layer 3403 is deposited via inkjets or slot die coating or gravure coating or a combination of them. The custom profiling of profiling polymer 3403 is performed via custom inkjet drop patterns or projection of heat pattern or both. A matched etch is performed to etch the profiled layer of polymer 3403 into the inorganic nanostructures 3401 as shown in FIG. 34C. This etch-back of polymer 3403 into inorganic nanostructures 3401 can be achieved through dry etching in a plasma. Different etch chamber configurations can be used, including capacitively coupled plasma chambers (i.e., a parallel plate configuration), CCP, or inductively coupled plasma chambers, ICP. The etch rates of polymer 3403 and inorganic material (nanostructures) 3401 can be controlled by adjusting the parameters of the etch process. Adjustable etch parameters include the process pressure (1 mTorr-1000 mTorr), gas flow rates (0.1-100 sccm), applied RF power (20 W-400 W), RF frequency (2-100 MHz), substrate temperature (−150° C. to 400° C.), gas chemistry (Ar, CF₄, CHF₃, O₂, SF₆, Cl₂, HBr, C₄F₈, H₂, He, N₂), and DC bias (5V-1000V) across the electrodes. In the ICP etch chamber configuration, the ICP power (20 W-2500 W) is an additional process parameter that can be tuned. In general, different combinations of the parameter set can yield etch selectivity, polymer: inorganic layer, in the range 0.1 to 10 where polymer: inorganic layer etch selectivity of <1 leads to pattern amplitude magnification, polymer: inorganic layer etch selectivity of >1 leads to pattern amplitude reduction, and polymer: inorganic layer etch selectivity that =1 leads to pattern amplitude replication. In FIG. 34D, a dry etching (e.g., oxygen plasma ashing) is performed to eliminate the polymer profiling material 3403 and leave the custom profiled multi-graded inorganic nanostructures 3401.

In FIG. 34D, a dry etching (e.g., oxygen plasma ashing) is performed to eliminate the polymer profiling material 3403 and leave the custom profiled multi-graded inorganic nanostructures 3401.

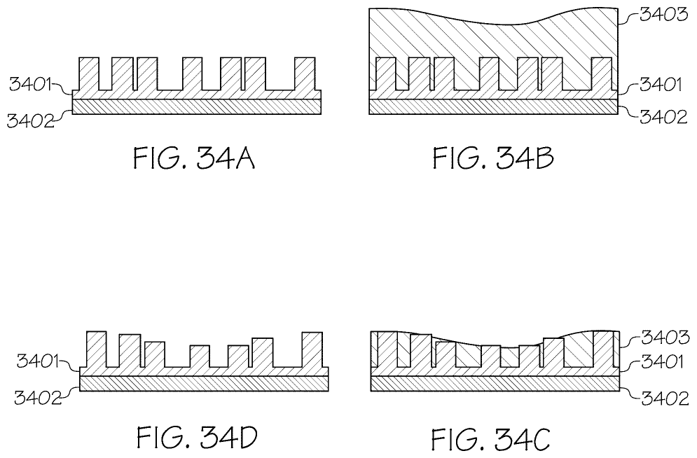

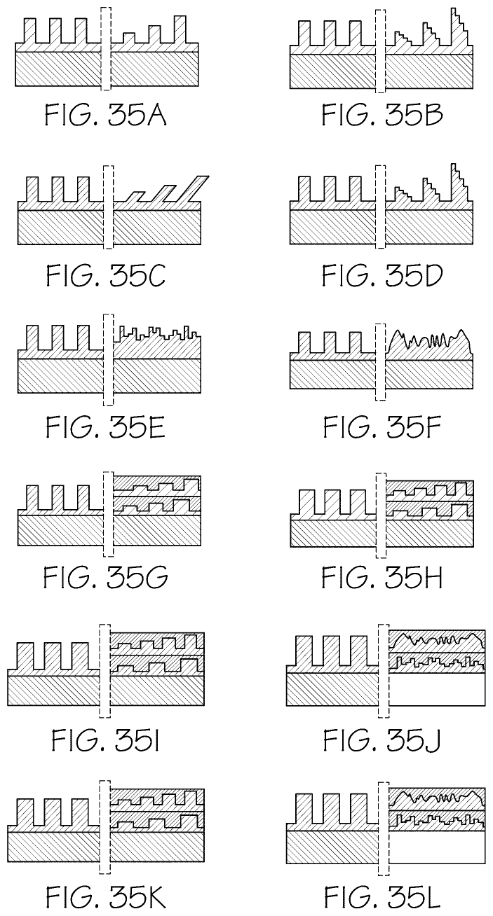

FIGS. 35A-35L illustrate exemplar nanostructures and materials for input and output gratings of waveguides used in applications, such as augmented reality and mixed reality (collectively, XR). In particular, FIGS. 35A-35L illustrate the various nanostructures and materials that include the input and output gratings of diffractive optical elements used in applications, such as XR, in accordance with an embodiment of the present disclosure.

FIG. 35A illustrates nanostructures made of a high index polymer with multi-graded patterns in the output gratings.

FIG. 35B illustrates a multi-graded, multi-tiered output grating with other parameters similar to the ones shown in FIG. 35A.

FIG. 35C illustrates nanostructures made out of high index inorganic materials (e.g., silicon nitride) with slanted multi-graded structures for output gratings.

FIG. 35D illustrates high index inorganic nanostructures with multi-tiered, multi-graded nanostructures.

FIG. 35E illustrates a high index inorganic nanostructure with patterns fabricated via computer generated holograms on the output gratings.

FIG. 35F illustrates high index inorganic nanostructures with analog surface relief gratings for the output gratings.

FIG. 35G illustrates a multi-layer high index polymer grating with silicon dioxide inter-fill as the output grating and high index inorganic nanostructures as the input grating.

FIG. 35H illustrates a multi-layer high index polymer grating with silicon dioxide inter-fill as the output grating and high index polymer nanostructures as the input grating.

FIG. 35I illustrates a multilayer high index inorganic grating with silicon dioxide inter-fill as the output grating.

FIG. 35J illustrates using the same materials as shown in FIG. 35I but the nanostructures in the output gratings can be fabricated via computer generated holograms or analog surface relief or a combination of both for each of the layers.

FIG. 35K illustrates a multi-layer high index inorganic grating with low index material inter-fill as the output grating.

FIG. 35L illustrates using the same materials as shown in FIG. 35K but the nanostructures in the output gratings can be fabricated via computer generated holograms or analog surface relief or a combination of both for each of the layers.

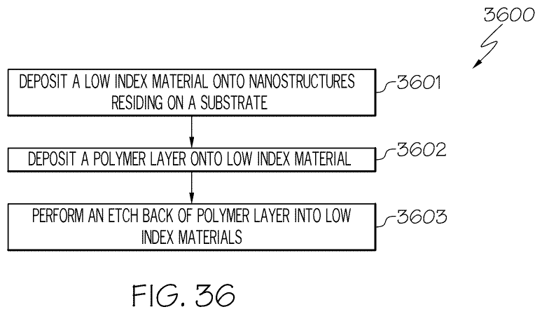

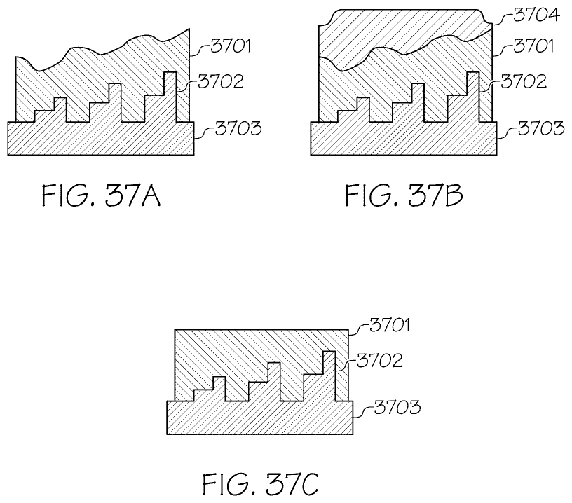

Referring now to FIG. 36, FIG. 36 is a flowchart of a method 3600 for fabricating high index inorganic waveguides with exemplar multi-tier, multi-graded nanostructures and a low index planar in accordance with an embodiment of the present disclosure. FIGS. 37A-37C depict the cross-sectional views for fabricating high index inorganic waveguides with exemplar multi-tier, multi-graded nanostructures and a low index planar using the steps of FIG. 36 in accordance with an embodiment of the present disclosure.

Referring to FIG. 36, in conjunction with FIGS. 37A-37C, in step 3601, a low index material (e.g., SiO₂) 3701 is deposited onto nanostructures 3702 residing on a substrate 3703 as shown in FIG. 37A.

In step 3602, a polymer layer 3704 is deposited onto low index material 3701, such as via vacuum deposition, as shown in FIG. 37B.

In step 3603, an etch back of polymer layer 3704 into low index material 3701 is performed. In one embodiment, such an etch back achieves a planarized low index material 3701 (e.g., SiO₂) parallel to substrate 3703.

FIGS. 36 and 37A-37C discuss the process steps to fabricate a single layer diffractive optical element made of high index inorganic or polymer nanostructures with an inter-fill of low index material. The low index material can have a refractive index between 1 and 1.5. The high index material can have a refractive index >1.5. Starting with a high index inorganic nanostructure shown in FIG. 36A fabricated via steps shown in FIGS. 23A-23H, the low index material 3701 is deposited on the high index nanostructures 3702. The deposition can be done via PECVD of materials, such as silicon dioxide, or via 3D nanoimprint lithography and atomic layer deposition of material, such as ZnO and Al₂O₃. FIG. 37B illustrates a polymer profiling layer 3704 that is deposited onto low index layer 3701. In one embodiment, layer 3701 is planarized by the use of nP3 (nanoscale programmable precision profiling). It is noted that the top interface of layer 3701 is made parallel to substrate 3703 since deposition of low index material 3701 will produce a low index layer that is parallel to the gradient in the high index nanostructures 3702. A matched etch process as shown in FIG. 37C is carried out to transfer the planar profile into the low index material layer 3701. This leaves behind the high index nanostructure 3702 with an inter-fill of low-index material 3701 that is parallel to substrate 3703. The thickness of low-index material 3701 above the tallest high-index nanostructures 3702 as shown in FIG. 37C can be 100 nm or 1 micrometer or several micrometers thereby maintaining the desired optical properties over the multi-graded and/or multi-tiered high index nanostructures 3702. It is noted that the planarization of low index material 3701 can also be achieved by chemical mechanical polishing (CMP).

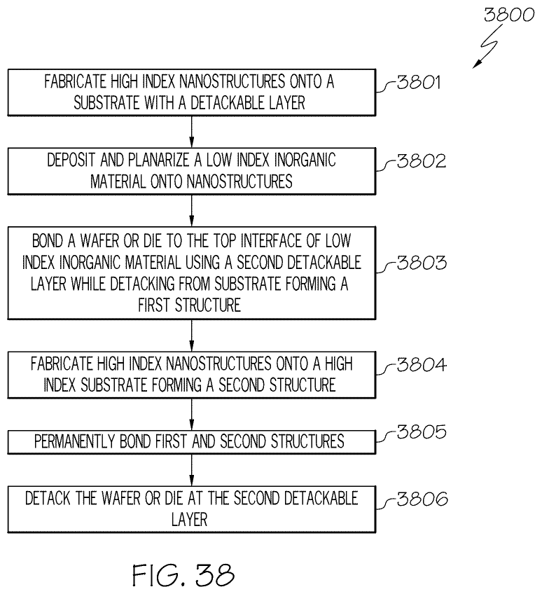

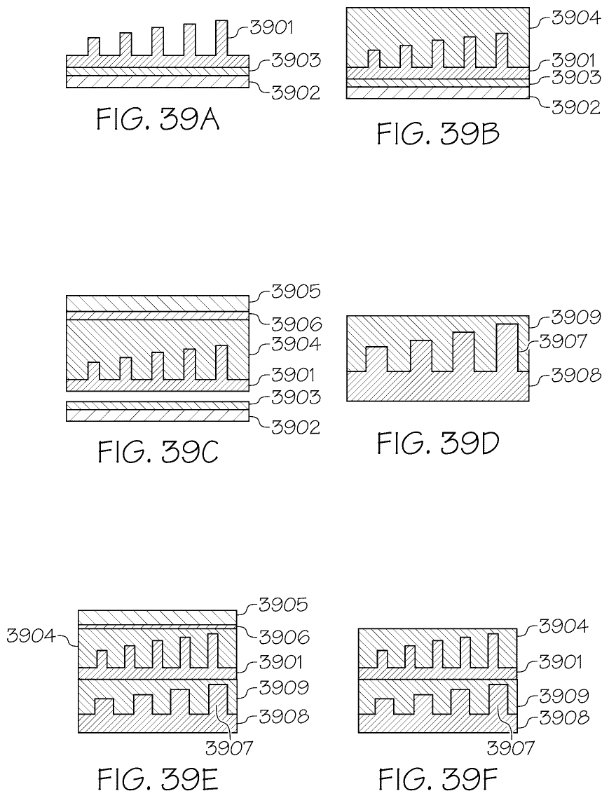

Referring now to FIG. 38, FIG. 38 is a flowchart of a method 3800 for fabricating multi-layer high index nanostructures for applications, such as XR, in accordance with an embodiment of the present disclosure. FIGS. 39A-39F depict the cross-sectional views for fabricating multi-layer high index nanostructures for applications, such as XR, using the steps of FIG. 38 in accordance with an embodiment of the present disclosure.

Referring to FIG. 38, in conjunction with FIGS. 39A-39F, in step 3801, high index nanostructures 3901 are fabricated onto a substrate 3902 with a detackable layer 3903 using the process of FIGS. 23A-23H as shown in FIG. 39A.

In step 3802, a low index inorganic material 3904 is deposited onto nanostructures 3901 and planarized using the process described in FIGS. 37A-37C as shown in FIG. 39B.

In step 3803, a wafer or die 3905 is bonded to the top interface of low index inorganic material 3904 using a second detackable layer 3906 while detacking from substrate 3902 as shown in FIG. 39C.

In step 3804, high index nanostructures 3907 are fabricated onto a high index substrate 3908 with a flat low index layer 3909 deposited on nanostructures 3907 as described in FIGS. 23A-23H and 37A-37C as shown in FIG. 39D.

In step 3805, the structures shown in FIG. 39C and 39D are permanently bonded using an adhesive layer or by direct bonding as shown in FIG. 39E.

In step 3806, the wafer or die 3905 is detacked at the second detackable layer 3906 as shown in FIG. 39F.

FIGS. 38 and 39A-39F describe the process steps for fabricating a multi-layer diffractive optical element where each layer can consist of a high index nanostructure and a low index inter-fill with a planar top surface parallel to the substrate.

FIG. 39A starts with a high index nanostructure 3901 on substrate 3902 with a detacking layer 3903 fabricated via steps shown in FIGS. 23A-23H. In one embodiment, detacking layer 3903 is a weak silane based polymer adhesive or water soluble adhesive, such as polyvinyl alcohol, or a light or heat switchable adhesive. In FIG. 39B, the high index nanostructures 3901 on detacking layer 3903 is covered by a planarized low index material 3904. A wafer or a die 3905 made of silicon or fused silica is temporarily bonded to the low index layer 3904 as shown in FIG. 39C. The temporary bonding layer can be a weak silane based polymer adhesive or water soluble adhesive, such as polyvinyl alcohol, or a light or heat switchable adhesive. The film stack is detacked from the detackable layer 3903 as shown in FIG. 39C. FIG. 39D illustrates a high index nanostructure 3907 with a low index inter fill 3909 as described in FIGS. 37A-37C. In FIG. 39E, a permanent bonding process is performed using a thin adhesive layer of organic material or a direct bonding process. In FIG. 39F, the temporarily bonded wafer or die 3905 is detacked which leaves behind the multilayer diffractive optical element.

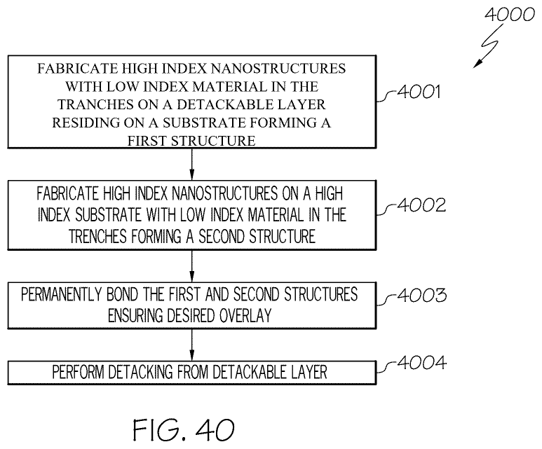

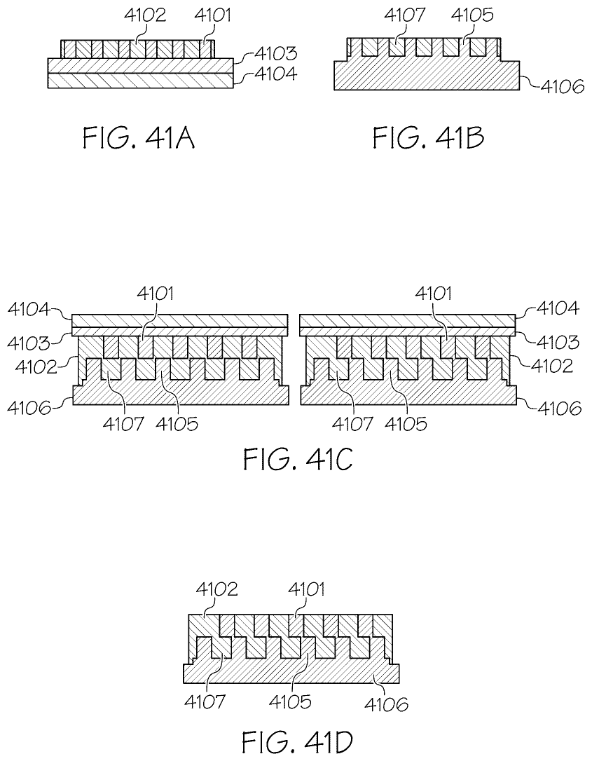

Referring now to FIG. 40, FIG. 40 is a flowchart of a method 4000 for fabricating multi-layer high index nanostructures with precise overlay for applications, such as augmented reality, in accordance with an embodiment of the present disclosure. FIGS. 41A-41D depict the cross-sectional views for fabricating multi-layer high index nanostructures with precise overlay using the steps of FIG. 40 in accordance with an embodiment of the present disclosure.

Referring to FIG. 40, in conjunction with FIGS. 41A-41D, in step 4001, high index nanostructures 4101 are fabricated with low index material 4102 in the tranches on a detackable layer 4103 residing on substrate 4104 using the process described in FIGS. 23A-23H and FIGS. 37A-37C.

In step 4002, high index nanostructures 4105 are fabricated on a high index substrate 4106 with low index material 4107 in the trenches using the process described in FIGS. 23A-23H and FIGS. 37A-37C.

In step 4003, the structures shown in FIGS. 41A and 41B are permanently bonded with overlay control as shown in FIG. 41C.

In step 4004, detacking from detackable layer 4103 is performed leaving behind the multi-layered nanostructure as shown FIG. 41D.

FIGS. 40 and 41A-41D describe the fabrication of multilayered diffractive optical elements with high index nanostructures, low index inter-fill and alternating structure requiring precise overlay. FIG. 41A starts with a high index nanostructure 4101 with a low index inter-fill 4102 bonded to a substrate 4104 using a detackable layer 4103. The high index nanostructure 4101 is fabricated using the steps described in FIGS. 23A-23H. In one embodiment, the etch process is prolonged for longer duration to etch the top layer of the high index inorganic material before bonding to substrate 4104 via detackable layer 4103. In one embodiment, low index material layer 4102 is etched for a longer duration as compared to FIG. 37C to eliminate the top layer of low index material 4102 over the high index nanostructure 4101 thereby leaving behind the film stack as shown in FIG. 41A. FIG. 41B illustrates the high index nanostructures 4105 with a low index inter-fill 4107 as shown in FIGS. 37A-37C. The 2 film stacks in FIGS. 41A and 41B are then permanently bonded to each other via a thin polymer adhesive film.

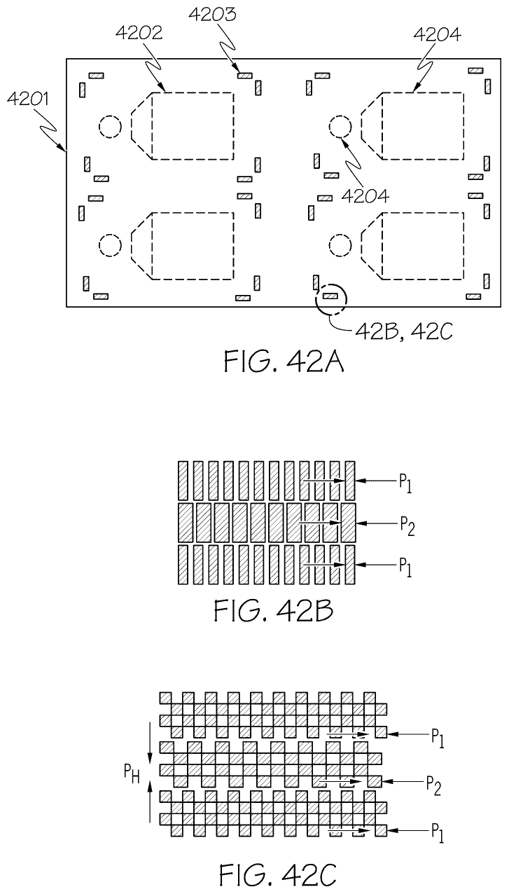

FIGS. 42A-42C illustrate a large area substrate 4201 typically made of glass with multiple cutouts of eyewear shaped devices 4202 in accordance with an embodiment of the present disclosure

Each device 4202 contains an input grating and output grating. In order to perform overlay as required for multilayer diffractive optical elements, Moire marks 4203 can be fabricated outside of the device region. 8 such locations have been shown in FIG. 42A. A similar Moire mark 4203 is fabricated on the die or wafer that is bonded to the diffractive optics area. The Moire pattern 4204 on the top wafer or die can include lines with critical dimensions denoted by P1 and P2 as shown in FIG. 42B. On the glass substrate, Moire marks 4203 can be a checkerboard pattern with critical dimensions P1, P2 and PH as shown in FIG. 42C. Interference patterns 4204 generated from the Moire marks 4203 allow magnification of small deviations or movements. The table below shows exemplar values for Moire parameters, such as P1, P2 and PH, and the corresponding sensing resolution achieved. These parameters can be varied as shown in the table below in order to integrate into a system with an optical microscope and precision alignment stage for overlay correction. Precision of the alignment stage and resolution and field of view of the optical microscope play an important role in determining the feasible sensing resolution and therefore the minimum achievable overlay errors.

| | | | Moiré | | Stage | Microscope |
|---|---|---|---|---|---|---|
| Capture | | | Mark Size | Sensing | Accuracy | Field of |
| Range Cₙ (μm) | P₁, P₂ (μm) | Fixed P_{H} (μm) | $L = ( 3 \frac{{P}_{1} , {P}_{2}}{[ {P}_{1} , {P}_{2} ]} ) ( μ m )$ | Resolution (nm) | (μm) (^{~}C_{R}/2) | View (mm) (^{~}2L) |
| *1 | 2, 2.05 | 1 | 492 | 0.6 | 0.5 | 1 |
| 10 | 20, 22 | 1 | 660 | 40 | 5 | 1 |
| 10 | 20, 21 | 1 | 837 | 30 | 5 | 2 |
| 10 | 20, 20.8 | 1 | 1,257 | 20 | 5 | 2 |
| 20 | 40, 45 | 1 | 1,080 | 60 | 10 | 2 |
| 20 | 40, 43 | 1 | 1,675 | 30 | 10 | 2 |
| 20 | 40, 42 | 1 | 2.515 | 20 | 10 | 5 |
| 50 | 100, 110 | 1 | 3,300 | 40 | 25 | 6 |
| 50 | 100, 107 | 1 | 4,187 | 30 | 25 | 8 |
| 50 | 100, 105 | 1 | 6,287 | 20 | 25 | 10 |

*Benchmark Parameters for J-FIL

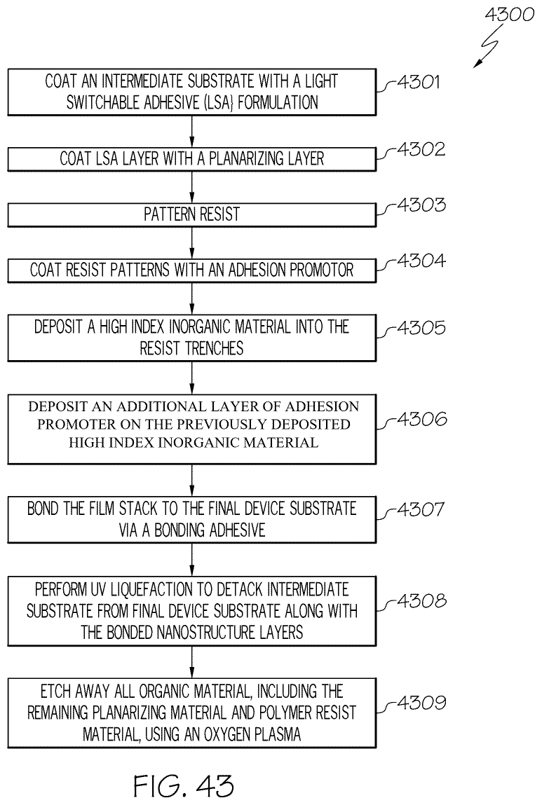

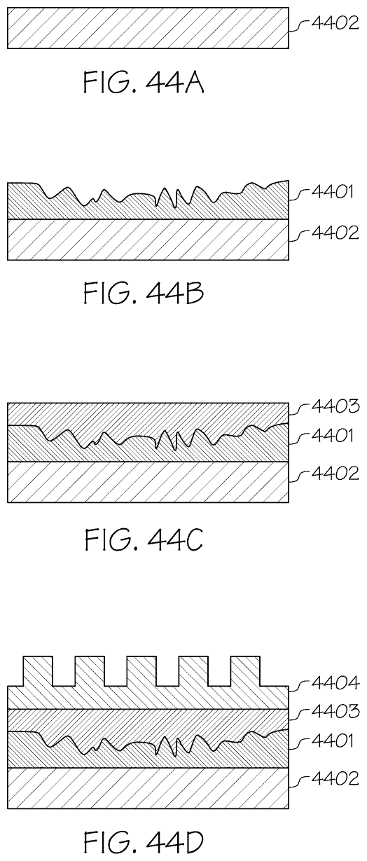

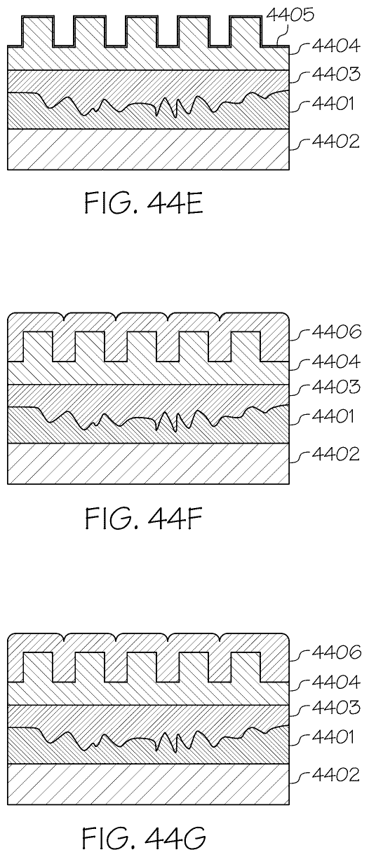

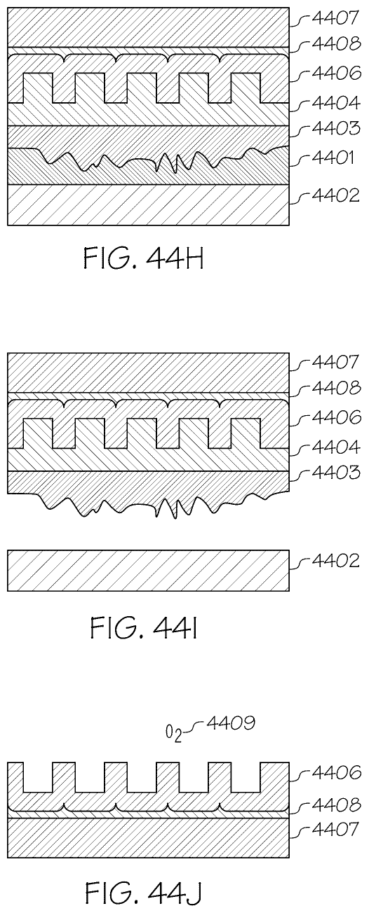

Referring now to FIG. 43, FIG. 43 is a flowchart of a method 4300 for performing the nHOC process with a light switchable adhesive as a detacking layer followed by planarization in accordance with an embodiment of the present disclosure. FIGS. 44A-44J depict the cross-sectional views for performing the nHOC process with a light switchable adhesive as a detacking layer followed by planarization using the steps of FIG. 43 in accordance with an embodiment of the present disclosure.

Referring to FIG. 43, in conjunction with FIG. 44A, in step 4301, an intermediate substrate 4402 is coated with an LSA (light switchable adhesive) formulation 4401 as shown in FIGS. 44A-44B. In one embodiment, intermediate substrate 4402 is rigid, such as silicon, fused silica, etc. In another embodiment, intermediate substrate 4402 is flexible, such as polycarbonate, PET, etc. In one embodiment, LSA formulation 4401 consists of crystallite formations.

In step 4302, LSA formulation 4401 is coated with a planarizing layer 4403 as shown in FIG. 44C. In one embodiment, planarizing layer 4403 is a water soluble polymer, such as polyvinyl alcohol. In another embodiment, planarizing layer 4403 is an imprint resist layer. In one embodiment, prior to coating LSA formulation 4401 with planarizing layer 4403, a blocking layer is deposited between LSA formulation 4401 and planarizing layer 4403. In one embodiment, such a blocking layer comprises chromium.

In step 4303, resist 4404 is deposited and patterned as shown in FIG. 44D.

In step 4304, resist patterns 4404 are coated with an adhesion promotor 4405 as shown in FIG. 44E. In one embodiment, adhesion promotor 4405 is TranSpin™, made by Canon Nanotechnologies.

In step 4305, a high index inorganic material 4406 is deposited into the resist trenches using processes, such as PECVD, as shown in FIG. 44F. In one embodiment, high index inorganic material 4406 is silicon nitride.

In step 4306, an additional layer of adhesion promotor 4405 is deposited onto the previously deposited high index inorganic material 4406 as shown in FIG. 44G.

In step 4307, the film stack of FIG. 44G is bonded to the final device substrate 4407 via a bonding adhesive 4408 as shown in FIG. 44H. In one embodiment, bonding adhesive 4408 is an imprint resist with a thickness of less than 10 nm or a high index organic resist. In one embodiment, fusion bonding is utilizing for bonding. In one embodiment, final device substrate 4407 has a matching refractive index with respect to the high index inorganic material 4406.

In step 4308, UV liquefaction is performed to detack intermediate substrate 4402 from final device substrate 4407 along with the bonded nanostructure layers as shown in FIG. 44I.

After detacking, in step 4309, an oxygen plasma 4409 is used to etch away all organic material, including the remaining planarizing material 4403 and polymer resist material 4404.

This nHOC process with LSA-based detacking layer can significantly improve process throughput by performing detacking in a few seconds.

The following discusses the nHOC process for high aspect ratio functional nanostructures.

A master template is fabricated using conventional techniques, such as E-beam lithography. In one embodiment, it is made out of structurally stable material, such as silicon dioxide, etc. necessary for sustaining disconnected nanostructures with high aspect ratios without collapse (for example, isolated dot). The patterns on the master template are the same structures that will eventually be transferred onto the substrate. This master template is then used to create an ‘Interim Template (IT)’ through Plate-to-Roll NIL where the interim template is made out of a flexible material which could potentially be held in a roll-to-roll configuration. The patterns on the IT are complementary or inverse tone to the master template and to the final desired pattern on the substrate. Hence, disconnected patterns on the master lead to connected patterns on the IT. This allows usage of conventional NIL to fabricate the IT where mechanical stresses during the template removal step do not damage the connected patterns. The patterns on the IT are comprised of an organic polymer which is UV crosslinked where the organic polymer can be entirely dry ashed away with O₂ plasma (comprised of C, O, H, N, etc.). The IT nanostructure material is carefully designed to contain a dielectric, such as a silica/glue interface, to enable detachment from its flexible base. The next process step uses the IT to pattern functional materials that necessarily contain a component, such as Si, Ti, etc. that will not be consumed by O₂ plasma. Following the dry ash step, high aspect ratio disconnected patterns that are prone to collapse are now patterned on the substrate. Now, an encapsulation approach is used, such as glancing angle e-beam evaporation of thermally compatible materials, to create a bridge on the pillars to prevent subsequent collapse.

The following is a description of the nHOC process for orthogonal structures on curved surfaces.

A process is described for patterning on smooth curved surfaces where the patterning is performed using templates made by standard planar substrate nanofabrication processes, such as lithography, etch, etc. and the final pattern is typically orthogonal to the local surface. The challenge in conventional imprint lithography is that the separation step would damage the IT and also the patterns placement will contain distortions associated with in-plane stresses generated due to the curvature in the IT when it is patterning the curved surface. Mechanical stresses on locally orthogonal patterns are high and likely to be damaged during template separation. The nHOC process of the present disclosure adapted for curved surfaces is described below.

A master template is fabricated using conventional techniques, such as E-beam lithography. It is made out of structurally stable material, such as silicon dioxide, etc. The patterns on the flat master template are the same structures that will eventually be transferred onto the substrate. This master template is then used to create an ‘Interim Template (IT)’ through Plate-to-Roll Nanoimprint Lithography (NIL) where the interim template is made out of a flexible material which could potentially be held in a roll-to-roll configuration. The patterns on the IT are complementary, or inverse tone, to the master template and to the final desired pattern on the substrate. This allows usage of conventional NIL to fabricate the IT. The patterns on the IT are comprised of an organic polymer which is UV crosslinked wherein the organic polymer can be entirely dry ashed away with O₂ plasma (comprised of C, O, H, N, etc.). The IT nanostructure material is carefully designed to contain a dielectric, such as a silica/glue interface, to enable detachment from its flexible base. It is also ensured that an intentional pattern distortion is induced in the IT which is opposite to the pattern distortion produced to curvature of IT along the curved substrate. The IT may be clamped from all directions to apply tension so as to create the plastic deformation necessary for complete wrapping of IT along the curved substrate. The next process step uses the IT to pattern functional materials that necessarily contain a component, such as Si, Ti, etc., that will not be consumed by O₂ plasma. The IT film material is chosen such that it is amenable to stretch necessary for proper wrapping of curved surfaces. Then, the IT is separated leaving behind the organic polymer nanostructure on the patterned substrate. Following the dry ash step, locally orthogonal nanostructures are now patterned on the substrate. Now, an encapsulation approach may be used, such as glancing angle e-beam evaporation of thermally compatible materials, to create a bridge on the pillars to prevent subsequent collapse.

The following is a description of the nHOC process for inclined functional nanostructures.

Patterning inclined functional nanostructures on a flat final substrate is challenging with conventional imprint lithography since it is likely that the inclined patterns will be ripped off during template separation due to the high mechanical stresses. Soft mold proposed as a solution has several limitations with respect to mold life, pattern fidelity, pitch control, etc. The nHOC process adapted for inclined functional nanostructures is described below.

A master template is fabricated using conventional techniques, such as E-beam lithography. It is made out of structurally stable material, such as silicon dioxide, etc. The patterns on the master template are the same structures that will eventually be transferred onto the substrate albeit with an inclination. This master template is then used to create an ‘Interim Template (IT)’ through Plate-to-Roll NIL where the interim template is made out of a flexible material which could potentially be held in a roll-to-roll configuration. The patterns on the IT are complementary to the master template and to the final desired pattern on the substrate. Conventional NIL is used to fabricate the IT. Hence, nanostructures on the IT are upright (locally orthogonal). It is noted that these patterns on the IT are made out of imprint resist. After removing the residual layer, the organic polymer layer below the resist undergoes an inclined etch on an inclined RIE tool. Therefore, inclined patterns are now transferred on the IT which comprise of an organic polymer which is UV crosslinked where the organic polymer can be entirely dry ashed away with O₂ plasma (comprised of C, O, H, N, etc.). The IT nanostructure material is carefully designed to contain a dielectric, such as a silica/glue interface, to enable detachment from its flexible base. The next process step uses the IT to pattern inclined nanostructures of functional materials that necessarily contain a component, such as Si, Ti, etc., that will not be consumed by O₂ plasma. After patterning, a dry ash step is performed to remove all the organic polymer transferred onto the substrate from the IT. Now, an encapsulation approach may be used, such as glancing angle c-beam evaporation of thermally compatible materials, to create a bridge on the pillars to prevent subsequent collapse.

Flexible material, such as polycarbonate, PET, etc. can be used as the backing layer for the patterned webs. They can be handled in a R2R configuration allowing high throughput pattern transfer. On the substrate side, flat substrates can be rigid (e.g., Si, quartz, etc.) or flexible, such as PC, PET, etc. Curved substrates can be polycarbonate or glass lens blanks. Previously flat substrates that have undergone surface profiling can also be used as curved substrates.

Regarding imprint resist, for conventional NIL, imprint resist formulation can comprise a considerable amount of components having similar volatility, dissolved in a solvent that is considerably more volatile than the rest of the components. The solvent role is to dilute the required quantity of imprint resist to a higher volume thus allowing for a better way of spreading small amounts of imprint resist over the substrate and managing the final dry film thickness starting from a thicker initial wet film. Once the imprint resist solution is deposited on the substrate or the interim template (IT), the solvent evaporates first while the rest of the components evaporate at a much lower rate due to their lower volatility. This results in a mixture containing higher concentration of the other components and residual or negligible amounts of solvent. Appropriately formulated systems may perform satisfactorily under a range of compositions. Formulation design may take into account the expected amount of material that needs to be evaporated, such that the optimum range of component ratios is not disrupted. Further, certain components, such as the photoinitiator or crosslinkers, will almost always be less volatile, as seen in the table below. Besides solvents, an imprint resist formulation may contain a mixture of some, or all the following components: an initiator; polymerizable monomers with one active group; polymerizable monomers with more than one active group referred to in the art as crosslinkers; and surfactants. This list is not exhaustive as other components may be present according to desired performance and applications. Examples of relevant components are shown in the table below.

| Role | Material |
|---|---|
| Monomers | 2-Ethylhexyl methacrylate |
| | Cyclohexyl methacrylate |
| | Isobornyl methacrylate |
| | Tetrahydrofurfuryl methacrylate |
| | Benzyl methacrylate |
| Crosslinker | Ethylene glycol dimethacrylate |
| Surfactant | 1H,1H,2H,2H- |
| | Perfluorodecyltriethoxysilane |
| Photoinitiators | Irgacure 184 |
| | Irgacure 819 |
| | Irgacure 2959 |
| Solvent | MIBK Ethyl acetate |

Organic polymers, such as PMMA, etc., can also be chosen for nanostructure patterning. Functional material that are finally patterned on the substrate can include high index materials that contain Si, Ti, etc. so as to not be consumed by O₂ plasma.

The following table denotes the elements involved in an etch barrier material that can be used in the process of reactive ion etching the above mentioned imprint resist. It is noted that the RIE step in the imprint resist with this etch barrier material can be a vertical etch or slant etch:

| Role | Material |
|---|---|
| Monomers | Butyl acylrate |
| | Methyl methacrylate |
| | Methyl acrylate |
| Silylated monomer | Methacryloxypropyl tris(tri- |
| | methylsiloxy) silane |
| | (3-acryloxypropyl) tris(tri- |
| | methylsiloxy)-silane |
| Dimethyl siloxane | (Acryloxypropyl) methylsiloxane |
| derivative | dimethylsiloxane copolymer |
| | (Acryloxypropyl) methylsiloxane |
| | homopolymer |
| | Acryloxy terminated |
| | polydimethylsiloxane |
| Free radical | Irgacure 184 |
| generator | Irgacure 819 |
| Crosslinking agent | 1,3-bis(3-methacryloxypropyl)- |
| | tetramethyl disiloxane |

As a result of the foregoing, the embodiments of the present disclosure provide a means for providing high-throughput fabrication of functional nanostructures with complex geometries on planar and non-planar substrates.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for fabricating multi-tiered, multi-graded imprint lithography templates, the method comprising:
depositing a first profiled polymer layer onto a patterned multi-tiered primary material, wherein said patterned multi-tiered primary material comprises a hard mask on a top surface;
etching said first profiled polymer layer and said patterned multi-tiered primary material thereby forming a graded depth in a lower tier of said multi-tiered primary material;
selectively removing said etched first profiled polymer layer thereby forming an intermediate multi-tiered multi-graded primary material;
selectively stripping said hard mask from a top surface of said intermediate multi-tiered multi-graded primary material to create a hard mask free intermediate multi-tiered multi-graded primary material;
depositing a second profiled polymer layer onto said hard mask free intermediate multitiered multi-graded primary material;
etching said second profiled polymer layer and said patterned multi-tiered primary material thereby forming a profiled surface comprising regions of said second profiled polymer and regions of said patterned multi-tiered primary material, wherein a top tier of said multi-tiered primary material has been etched along with said second profiled polymer layer; and
selectively removing said etched second profiled polymer layer thereby forming a final patterned multi-tiered multi-graded primary material.

2. The method as recited in claim 1, wherein said patterned multi-tiered primary material is made from silicon dioxide.

3. The method as recited in claim 1, wherein said hard mask comprise one or more of the following: Cr, CrO, CrON, MoSiO, MoSiON, CrF, SiN, CrN, CrOCN, SiCrO, WSi and ZrSiO.

4. The method as recited in claim 1, wherein said deposition of said first profiled polymer layer is performed via slot die coating, inkjet dispensing, gravure coating or a combination of said slot die coating, inkjet dispensing and gravure coating.

5. The method as recited in claim 1, wherein said deposition of said second profiled polymer layer is performed via slot die coating, inkjet dispensing, gravure coating or a combination of said slot die coating, inkjet dispensing and gravure coating.

6. The method as recited in claim 1, wherein said etching is reactive ion etching.

7. The method as recited in claim 1, wherein said selective removal of said first profiled polymer layer and said second profiled polymer layer is performed via O₂ plasma ashing.

8. A method for fabricating multi-tiered, multi-graded imprint lithography templates, the method comprising:
depositing a first profiled polymer layer onto a patterned multi-tiered primary material;
etching said first profiled polymer layer and said patterned multi-tiered primary material thereby forming a composite profiled surface comprising regions of said first profiled polymer layer and regions of said patterned multi-tiered primary material, wherein a top tier of said multi-tiered primary material has been etched along with said first profiled polymer layer;
selectively depositing a hard mask cap on to said regions of said patterned multi-tiered primary material on said composite profiled surface;
selectively removing said etched first profiled polymer layer thereby forming an intermediate multi-tiered multi-graded primary material;
depositing a second profiled polymer layer onto said intermediate multi-tiered multi-graded primary material;
etching said second profiled polymer layer and said patterned multi-tiered primary material thereby forming a graded depth in a lower tier of said multi-tiered primary material; and
selectively removing said etched second profiled polymer layer thereby forming a patterned multi-tiered multi-graded primary material with a hard mask.

9. The method as recited in claim 8, wherein said patterned multi-tiered primary material is made from silicon dioxide.

10. The method as recited in claim 8, wherein said selectively deposited hard mask comprises one of the following: TiOx, Pt and Pd.

11. The method as recited in claim 8, wherein said selective deposition of hard mask cap is performed via selective atomic layer deposition.

12. The method as recited in claim 8, wherein said deposition of said first profiled polymer layer is performed via slot die coating, inkjet dispensing, gravure coating, vacuum deposition or a combination of said slot die coating, said inkjet dispensing, said gravure coating, and said vacuum deposition.

13. The method as recited in claim 8, wherein said deposition of said second profiled polymer layer is performed via slot die coating, inkjet dispensing, gravure coating, vacuum deposition or a combination of said slot die coating, said inkjet dispensing, said gravure coating, and said vacuum deposition.

14. The method as recited in claim 8, wherein said etching is reactive ion etching.

15. The method as recited in claim 8, wherein said selective removal of said first profiled polymer layer and said second profiled polymer layer is performed via O₂ plasma ashing.

16. A method for fabricating functional optical components, the method comprising:
depositing a detackable adhesive layer on an intermediate substrate;
depositing a curable liquid onto said detackable adhesive layer on said intermediate substrate;
using an imprint template to transfer patterns onto said curable liquid followed by curing thereby forming an imprinted patterned material on said intermediate substrate;
depositing a layer of functional material on said imprinted patterned material;
depositing a polymer layer on top of said functional material layer;
performing a correlated etch of said polymer layer and said functional material layer thereby forming an etched functional material surface;
bonding said etched functional material surface to a final substrate; and
detacking said imprinted patterned material from said intermediate substrate at said detackable adhesive layer.

17. The method as recited in claim 16, wherein said imprinted patterned material is eliminated selectively using O2 plasma ashing resulting in a patterned functional material on said final substrate.

18. The method as recited in claim 16, wherein said imprint template has patterns comprised of UV crosslinked organic polymer.

19. The method as recited in claim 18, wherein said patterns have an encapsulation layer of inorganic material.

20. The method as recited in claim 18, wherein said patterns are multi-tiered or multi-graded or both.

21. The method as recited in claim 16, wherein said detackable adhesive layer is a light switchable polymer adhesive.

22. The method as recited in claim 16, wherein said detacking of said detackable adhesive layer is performed by applying light or heat.

23. The method as recited in claim 16, wherein said detackable layer is a silane-based adhesive.

24. The method as recited in claim 16, wherein said detackable layer has a lower adhesion strength compared to a strength of said bonding.

25. The method as recited in claim 16, wherein said deposition of said detackable adhesive layer is performed using slot die coating, inkjet dispensing, gravure coating or a combination of said slot die coating, inkjet dispensing, and gravure coating.

26. The method as recited in claim 16, wherein said deposition of curable liquid film is performed using slot die coating, inkjet dispensing, gravure coating or a combination of said slot die coating, inkjet dispensing, and gravure coating.

27. The method as recited in claim 16, wherein said curable film is photo-curable.

28. The method as recited in claim 16, wherein said curable film in heat curable.

29. The method as recited in claim 16, wherein said intermediate substrate is a composite of multiple layers of organic and inorganic films.

30. The method as recited in claim 16, wherein said imprinted patterned material is used as a mask to etch an underlying polymer layer where said imprinted patterned material contains silicon and where said etching is reactive ion etching in a vertical or slanted direction with respect to said intermediate substrate.

31. The method as recited in claim 16, wherein said final substrate is planar or curved.

32. The method as recited in claim 16, wherein said functional material has an optical index exceeding 1.6 in a visible spectrum.

33. The method as recited in claim 16, wherein said functional material is comprised of one of the following elements: Si, Ti, and Ga.

34. The method as recited in claim 16, wherein said deposition of said functional material is performed using slot die coating, inkjet dispensing, gravure coating, vacuum deposition or a combination of said slot die coating, inkjet dispensing, gravure coating, and vacuum deposition.

35. The method as recited in claim 16, wherein said deposition of said polymer layer is performed using slot die coating, inkjet dispensing, gravure coating or a combination of said slot die coating, inkjet dispensing, and gravure coating.

36. The method as recited in claim 16, wherein said bonding of said etched functional material surface onto said final substrate comprises a connecting polymer layer in between.

37. The method as recited in claim 16, wherein said bonding is a direct bonding between inorganic layers.

38. The method as recited in claim 16, wherein a functional optical component is a waveguide.

39. The method as recited in claim 16, wherein said intermediate substrate is substantially rigid or flexible.

40. The method as recited in claim 16, wherein said final substrate is substantially rigid or flexible.

41. The method as recited in claim 16, wherein said final substrate has a refractive index exceeding 1.5.

42. The method as recited in claim 16, wherein said polymer layer is patterned into a moth eye structure.

43. A method for fabricating diffractive optical elements with customizable pattern heights, the method comprising:
patterning nanostructures on a substrate;
depositing one or more layers of contrasting material over said patterned nanostructures;
custom profiling said contrasting material forming a custom profile;
etching said custom profile into said patterned nanostructures thereby producing a patterned nanostructure with custom pattern heights with trenches filled with said contrasting material; and
eliminating said contrasting material from said trenches leaving behind said nanostructure with custom pattern heights.

44. The method as recited in claim 43, wherein said nanostructures comprise a polymer material or inorganic material.

45. The method as recited in claim 43, wherein said contrasting material comprises a combination of polymer material and inorganic material.

46. The method as recited in claim 43, wherein said custom profiling of said contrasting material is performed via irradiating a spatially varying heat input.

47. There method as recited in claim 43, wherein said custom profiling of said contrasting material is performed via dispensing a polymer with a spatially varying drop pattern from an inkjet.

48. The method as recited in claim 43, wherein said etching of said custom profile is performed via reactive ion etching.

49. The method as recited in claim 43, wherein said elimination of contrasting material is performed via oxygen plasma cleaning for polymer contrasting material.

50. The method as recited in claim 43, wherein said elimination of contrasting material is performed via selective chemical etching for inorganic contrasting material.

51. A method for fabricating multi-layered diffractive optical elements, the method comprising:
patterning nanostructures of high index material;
depositing low index material over said patterned nanostructure of said high index material as an inter-fill;
planarizing said low index material thereby forming a single layer of high index nanostructure with planarized low index material inter-fill; and
bonding said single layer of high index nanostructure with planarized low index material inter-fill to another single layer of said high index nanostructure with planarized low index material inter-fill.

52. The method as recited in claim 51, wherein said low index material inter-fill is silicon dioxide.

53. The method as recited in claim 51, wherein said low index material inter-fill is fabricated via 3D nanoimprint lithography and atomic layer deposition.

54. The method as recited in claim 51, wherein said planarization is performed via chemical mechanical polishing.

55. The method as recited in claim 51, wherein said planarization is performed via deposition of planarizing film via inkjet dispense or slot die coating or a combination of both.

56. The method as recited in claim 51, wherein said planarization is performed via irradiating a spatial heat profile on a planarizing film.

57. The method as recited in claim 51, wherein said bonding comprises a connecting polymer layer in between said single layers.

58. The method as recited in claim 51, wherein said bonding is a direct bonding between inorganic layers.
